(19) United States
(12) Patent Application Publication
(10) Pub. No.: US 2008/0302417 A1
(43) Pub. Date: Dec. 11, 2008

(54) FILLER SHEET FOR SOLAR CELL MODULE, AND SOLAR CELL MODULE USING THE SAME

(76) Inventors: Isao INOUE, Tokyo (JP); Koujiro OHKAWA, Tokyo (JP); Takaki MIYACHI, Tokyo (JP); Kasumi OI, Tokyo (JP)

Correspondence Address: LADAS & PARRY LLP, 224 SOUTH MICHIGAN AVENUE, SUITE 1600, CHICAGO, IL, 60604, US

(21) Appl. No.: 12/189,246

(22) Filed: Aug. 11, 2008

Related U.S. Application Data
(62) Division of application No. 10/537,733, filed on Jun. 7, 2005.

(30) Foreign Application Priority Data
Dec. 16, 2002 (JP) 2002-363273

(51) Int. Cl. H01L 31/00

(52) U.S. Cl. 136/256

(57) ABSTRACT

A main object of the invention is to provide a filler sheet for a solar cell module which is excellent in various properties such as strength, endurance, weatherability, heat resistance, water resistance, light resistance, wind pressure resistance, hailstorm resistance, and vacuum laminating suitability, and has very good thermal melting/bonding property without being affected by production conditions and others, and which makes it possible to produce a solar cell module, suitable for various use purposes, stably at low costs; and a solar cell module using the same.

In order to attain the object, the invention provides, as a filler sheet for solar cell element, a filler sheet made of a resin film produced by a resin composition comprising a copolymer of an α-olefin and an ethylenic unsaturated silane compound, or a modified or condensed body thereof, and one or more selected from the group consisting of a light resisting agent, an ultraviolet absorbent and a thermal stabilizer; and a filler sheet made of a resin film produced by a resin composition comprising a maleic anhydride modified polyolefin.

### TECHNICAL FIELD

The present invention relates to a filler sheet for a solar cell module, and a solar cell module using the same, more specifically, a very useful filler sheet for a solar cell module which is excellent in strength and endurance and further excellent in various properties such as weatherability, heat resistance, light resistance, water resistance, wind pressure resistance, hailstorm resistance, and vacuum laminating suitability, and has very good thermal melting/bonding property without being affected by production conditions for heating, compression and others for producing a solar cell module, and which makes it possible to produce a solar cell module stably at low costs; and a solar cell module using the same.

### BACKGROUND ART

In recent years, attention has been paid to a solar cell as a clean energy source in light of an upsurge of consciousness of environmental problems, and at present solar cell modules in various forms have been developed and suggested.

In general, the solar cell modules are each produced by first producing, for example, a crystal silicon solar cell element or amorphous silicon solar cell element and then utilizing a lamination process of using such a solar cell element to laminate a front face protecting sheet, a filler sheet, the solar cell element as a photoelectromotive force element, a filler sheet, a rear face protecting sheet, and so on in order that these members have been described and next heating and compressing these members while vacuum-sucking the members, or some other process.

At first, the solar cell modules were applied to electric calculators. Thereafter, the modules have been applied to various electronic apparatuses, and the application range thereof has rapidly been spreading for the people's livelihood. It is said that the most important theme in the future is a realization of large-scale concentrated type solar cell power generation.

Incidentally, about the filler sheets laminated on the front face side and the rear face side of the solar cell element, as a photoelectromotive force element, in the solar cell modules, sunlight is radiated into the filler sheet positioned on the front face side. Thus, the filler sheet needs to have transparency that the sheet transmits this light. However, the filler sheet positioned on the rear face side may not necessarily have transparency.

Needless to say, the filler sheets which constitute the solar cell modules have adhesiveness to the front face protecting sheet or the rear face protecting sheet. Furthermore, it is said that the filler sheets need to have thermal plasticity for fulfilling a function of keeping the smoothness of both of the front and rear faces of the solar cell element as a photoelectromotive force element, be excellent in strength and endurance and further various properties such as weatherability, heat resistance, light resistance, water resistance, wind pressure resistance and hailstorm resistance, and be further excellent in scratch resistance, impact absorptivity, and others.

At present, as the material constituting the filler sheets, there is most generally used a filler sheet which has a thickness of 400 to 600 μm and is made of ethylene-vinyl acetate copolymer from the viewpoint of the processability, the workability, the production costs thereof, and the like (see, for example, Japanese Patent Application Laid-Open Nos. 58-63178 (claims), and 59-22978 (claims)).

However, when the above-mentioned filler sheet, 400 to 600 μm in thickness, made of ethylene-vinyl acetate copolymer or the like is used and this is directly laminated to produce a solar cell module by a lamination process of laminating this filler sheet, a front face protecting sheet, a solar cell element, a rear face protecting sheet and others, and heating and compressing the resultant laminate while vacuum-sucking the laminate wholly, or some other process, the filler sheet, made of ethylene-vinyl acetate copolymer or the like, is affected such as by conditions for the heating and compression, or the storage or preservation of the produced solar cell module. As a result, for example, the ethylene-vinyl acetate copolymer thermally shrinks or thermally decomposes to release acetic acid. As a result, a decomposition gas and a decomposition product of the acetic acid gas, and others are generated so as to produce a bad effect on the solar cell module, thereby resulting in, for example, corrosion or deterioration of electrodes constituting the solar cell module, a drop in electric power generation, or thereby causing the decomposition gas or the like to react with amorphous portions of silicon constituting the solar cell element so as to bring about a fall in electromotive force and other problems. Thus, there are problems that the solar cell module is not sufficiently satisfactory in thermal melting/bonding property when being heated and compressed, storability, preservability and others, and difficulty is found in producing the solar cell module stably at low costs.

Furthermore, when the ethylene-vinyl acetate thermally shrinks or thermally decomposes so that acetic acid is released to generate a decomposition gas such as acetic acid gas as described above, the working environment therefor and so on are deteriorated so that effect on workers and others cannot be avoided. Accordingly, the environment for the production should be unavoidably improved. As a result, costs are remarkably increased and the productivity and the like thereof are remarkably hindered.

Additionally, the above-mentioned ethylene-vinyl acetate copolymer or similar resin itself is somewhat insufficient in strength, endurance and other properties, and is not very good in various properties such as weatherability, heat resistance, light resistance, wind pressure resistance, and hailstorm resistance. The resin is deteriorated by, for example, ultraviolet rays out of sunlight rays so as to cause color changes such as yellowing, thereby resulting in a problem that the design or decoration property is remarkably damaged.

### DISCLOSURE OF THE INVENTION

In light of the above-mentioned problems, the present invention has been made, and provides a very useful filler sheet for a solar cell module that is made of a material which is excellent in strength and endurance and further excellent in various properties such as weatherability, heat resistance, water resistance, light resistance, wind pressure resistance, hailstorm resistance, and vacuum laminating suitability without being affected by solar cell module producing conditions, which has very good thermal melting/bonding property without being affected by production conditions for heating, compression and others for producing a solar cell module, and which makes it possible to produce a solar cell module suitable for various use purposes stably at low costs; and a solar cell module using the same.

The present inventors have made very researches about filler sheets for solar cell module to solve problems as described above. As a result, the inventors have paid attention to a filler sheet made of a resin film produced by a resin composition comprising a copolymer of an α-olefin and an ethylenic unsaturated silane compound, or a modified or condensed body thereof, and one or more selected from the group consisting of a light resisting agent, an ultraviolet absorbent and a thermal stabilizer; and as a filler sheet laminated on the front face and rear face sides of a solar cell element instead of any conventional filler sheet made of ethylene-vinyl acetate copolymer or the like, the inventors have made a filler sheet of a resin film made of the above-mentioned resin composition, which comprises a copolymer of an α-olefin and an ethylenic unsaturated silane compound, or a modified or condensed body thereof, and one or more selected from the group consisting of a light resisting agent, an ultraviolet absorbent and a thermal stabilizer. The inventors have produced a solar cell module by use of a lamination process of laminating, firstly, a front face protecting sheet, a filler sheet made of a resin film produced by a resin composition comprising a copolymer of an α-olefin and an ethylenic unsaturated silane compound, or a modified or condensed body thereof, and one or more selected from the group consisting of a light resisting agent, an ultraviolet absorbent and a thermal stabilizer, a solar cell element, a filler sheet made of a resin film produced by a resin composition comprising a copolymer of an α-olefin and an ethylenic unsaturated silane compound, or a modified or condensed body thereof, and one or more selected from the group consisting of a light resisting agent, an ultraviolet absorbent and a thermal stabilizer, and a rear face protecting sheet in sequence, and secondly heating and compressing these members while vacuum-sucking the members wholly, or some other process. As a result, the inventors have found out that the above-mentioned filler sheet, which is made of a resin film produced by a resin composition comprising a copolymer of an α-olefin and an ethylenic unsaturated silane compound, or a modified or condensed body thereof, and one or more selected from the group consisting of a light resisting agent, an ultraviolet absorbent and a thermal stabilizer, is excellent in strength and endurance and further excellent in various properties such as weatherability, heat resistance, water resistance, light resistance, wind pressure resistance, hailstorm resistance, and vacuum laminating suitability; has very good thermal melting/bonding property without being affected by production conditions for heating, compression and others for producing the solar cell module; and makes it possible to produce stably a very useful solar cell module suitable for various use purposes at low costs. Thus, the present invention has been completed.

The inventors have found out that the use of a filler sheet made of a resin film produced by a resin composition comprising a maleic anhydride modified polyolefin as a filler sheet laminated on the front face side and the rear face side of a solar cell element makes it possible to produce the same advantageous effects as in the case of using a resin film produced by a resin composition comprising a copolymer of an α-olefin and an ethylenic unsaturated silane compound, or a modified or condensed body thereof, and one or more selected from the group consisting of a light resisting agent, an ultraviolet absorbent and a thermal stabilizer, and additionally the filler sheet is excellent in stable adhesiveness to a front face protecting sheet or a rear face protecting sheet. Thus, the present invention has been completed.

Accordingly, the present invention relates to a filler sheet for a solar cell module, which is formed as a filler sheet laminated on the front face and rear face sides of a solar cell element, and is made of a resin film produced by a resin composition comprising a copolymer of an α-olefin and an ethylenic unsaturated silane compound, or a modified or condensed body thereof, and one or more selected from the group consisting of a light resisting agent, an ultraviolet absorbent and a thermal stabilizer; and a solar cell module using the same.

The present invention also relates to a filler sheet for a solar cell module, which is formed as a filler sheet laminated on the front face and rear face sides of a solar cell element, and is made of a resin film produced by a resin composition comprising a maleic anhydride modified polyolefin; and a solar cell module using the same.

The filler sheet according to the present invention which is made of a resin film produced by a resin composition comprising a copolymer of an α-olefin and an ethylenic unsaturated silane compound, or a modified or condensed body thereof, and one or more selected from the group consisting of a light resisting agent, an ultraviolet absorbent and a thermal stabilizer is excellent in strength and endurance and further excellent in various properties such as weatherability, heat resistance, water resistance, light resistance, wind pressure resistance, hailstorm resistance, and vacuum laminating suitability; and has very good thermal melting/bonding property without being affected by production conditions for heating, compression and others for producing a solar cell module. The use of this filler sheet makes it possible to produce stably a very useful solar cell module suitable for various use purposes at low costs.

Furthermore, the filler sheet according to the present invention which is made of a resin film produced by a resin composition comprising a maleic anhydride modified polyolefin is excellent in the above-mentioned various properties. The use of this filler sheet makes it possible to exhibit excellent stable adhesiveness to a surface-treated front face protecting sheet or rear face protecting sheet also.

### BRIEF DESCRIPTION OF THE DRAWING

FIG. 1 is a view which schematically illustrates a layer structure which is an example of a solar cell module produced by use of a filler sheet according to the present invention.

### BEST MODES FOR CARRYING OUT THE INVENTION

The present invention will be described in more detail hereinafter.

In the present invention, a sheet means both of a product in a sheet form and a product in a film form, and a film means both of a product in a film form and a product in a sheet form.

### [1] Filler Sheet

First, the filler sheet, which is laminated on both of the front side face and the rear side face of a solar cell element as a photoelectromotive force element in the present invention, is described. As described above, sunlight is radiated into the filler sheet laminated on the front face side of the solar cell element, and thus the filler sheet needs to have such a transparency that the sheet transmits the light. Furthermore, the filler sheet needs to: have adhesiveness to a front face protecting sheet; have thermal plasticity for fulfilling a function of keeping the smoothness of the front face of the solar cell element, as a photoelectromotive force element; be excellent in strength and endurance and further excellent in various properties such as weatherability, heat resistance, light resistance, water resistance, wind pressure resistance, hailstorm resistance, and vacuum laminating suitability in order to protect the solar cell element, as a photoelectromotive force element; have very good thermal melting/bonding property without being affected by production conditions for heating, compression and others for producing a solar cell module; and be excellent in scratch resistance, impact absorptivity, and others.

On the other hand, the filler sheet laminated on the rear face side of the solar cell element needs to: have adhesiveness to a rear face protecting sheet in the same manner as the filler sheet laminated on the front face side of the solar element; have thermal plasticity for fulfilling a function of keeping the smoothness of the rear face of the solar cell element, as a photoelectromotive force element; be excellent in strength and various properties such as weatherability, heat resistance, light resistance, water resistance, wind pressure resistance, hailstorm resistance, and vacuum laminating suitability in order to protect the solar cell element, as a photoelectromotive force element; be very rich in endurance; and be excellent in scratch resistance, impact absorptivity, and others.

However, the filler sheet laminated on the rear face side of the solar cell element may not necessarily have transparency, which is different from the filler sheet laminated on the front face side of the solar cell element.

As the filler sheet having performances, functions, physical properties and others as described above, the following filler sheet is made in the present invention: a filler sheet made of a resin film produced by a resin composition comprising a copolymer of an α-olefin and an ethylenic unsaturated silane compound, or a modified or condensed body thereof, and one or more selected from the group consisting of a light resisting agent, an ultraviolet absorbent and a thermal stabilizer (the filler sheet being referred to as the filler sheet (A) as the case may be).

Furthermore, as the filler sheet having performances, functions, physical properties and others as described above, the following filler sheet is made in the present invention: a filler sheet made of a resin film produced by a resin composition comprising a maleic anhydride modified polyolefin (the filler sheet being referred to as the filler sheet (B) as the case may be).

In the present invention, on both of the front side face and the rear side face of a solar cell element, substantially the same material is used to make filler sheets.

Each of the filler sheet (A) and the filler sheet (B) will be described in detail hereinafter.

### 1. Filler Sheet (A)

The filler sheet (A) is made of a resin film produced by a resin composition comprising a copolymer of an α-olefin and an ethylenic unsaturated silane compound, or a modified or condensed body thereof, and one or more selected from the group consisting of a light resisting agent, an ultraviolet absorbent and a thermal stabilizer. The following will describe each of the components of this resin composition and a process for producing the resin composition.

### (1) Copolymer of an α-Olefin and an Ethylenic Unsaturated Silane Compound, or a Modified or Condensed Body Thereof

First, the copolymer of an α-olefin and an ethylenic unsaturated silane compound, or the modified or condensed body thereof, which constitutes the filler sheet (A) laminated on both of the front side face and the rear face side of a solar cell element in the present invention, is described. This copolymer of an α-olefin and an ethylenic unsaturated silane compound, or this modified or condensed body thereof may be, for example, a product obtained by using a desired reactor to random-copolymerize one or more α-olefins, one or more ethylenic unsaturated silane compounds and one or more optional other unsaturated monomers simultaneously or step by step, for example, at a pressure of 500 to 4000 kg/cm², preferably 1000 to 4000 kg/cm² and a temperature of 100 to 400° C., preferably 150 to 350° C. in the presence of a radical polymerization initiator and an optional chain transfer agent, and further modifying or condensing moieties of the silane compound(s) constituting the random copolymer produced by the copolymerization, thereby preparing a copolymer of the α-olefin(s) and the ethylenic unsaturated silane compound(s), or a modified or condensed body thereof.

The copolymer of an α-olefin and an ethylenic unsaturated silane compound, or the modified or condensed body in the present invention may also be, for example, a product obtained by using a desired reactor to polymerize one or more α-olefins and one or more optional other unsaturated monomers simultaneously or step by step in the presence of a radical polymerization initiator and an optional chain transfer agent in the same way as described above, next graft-copolymerizing the polyolefin polymer produced by the polymerization with one or more ethylenic unsaturated silane compounds, or initial condensed products or condensed products thereof, and further modifying or condensing moieties of the silane compound(s) constituting the graft copolymer produced by the copolymerization, thereby preparing a copolymer of the α-olefin(s) and the ethylenic unsaturated silane compound(s), or a modified or condensed body thereof.

In the copolymer of the α-olefin(s) and the ethylenic unsaturated silane compound(s), or the modified or condensed body thereof produced as described above, polymer moieties made of the α-olefin(s) are preferably made of low density polyethylene, linear low density polyethylene, a copolymer made of ethylene and an α-olefin and polymerized by use of a single site catalyst, or some other polymers from the viewpoint of such as transparency, working suitability, adhesiveness, and costs.

In the copolymer of the α-olefin(s) and the ethylenic unsaturated silane compound(s), or the modified or condensed body thereof produced as described above, for example, an alkyl group such as methyl or ethyl, an alkoxy group such as methoxy or ethoxy groups, a hydroxyl group, a halogen atom or some other group may be arbitrary bonded to Si atom moieties constituting the silane compounds).

As the α-olefin (s) in the above description, for example, one or more out of the following can be used: ethylene, propylene, 1-butene, isobutylene, 1-pentene, 2-methyl-1-butene, 3-methyl-1-butene, 1-hexene, 1-heptene, 1-octene, 1-nonene, and 1-decene.

As the ethylenic unsaturated silane compound(s) in the above description, for example, one or more out of the following can be used: vinyltrimethoxysilane, vinyltriethoxysilane, vinyltripropoxysilane, vinyltriisopropoxysilane, vinyltributoxysilane, vinyltripentyloxysilane, vinyltriphenoxysilane, vinyltribenzyloxysilane, vinyltrimethylenedioxysilane, vinyltriethylenedioxysilane, vinypropionyloxysilane, vinyltriacetoxysilane, or vinyltricarboxysilane.

As the other unsaturated monomer(s) in the above description, for example, one or more out of the following can be used: vinyl acetate, acrylic acid, methacrylic acid, itaconic acid, fumaric acid, maleic acid, methyl acrylate, methyl methacrylate, ethyl acrylate, styrene, acrylonitrile, methacrylonitrile, or vinyl alcohol.

In the case where the copolymer is modified or condensed in the above description, other silane compounds and so on can be used.

As the radical polymerization initiator in the above description, for example, the following can be used: an organic peroxide such as lauroylperoxide, dipropionylperoxide, benzoylperoxide, di-t-butylperoxide, t-butylhydroperoxide, t-butylperoxy isobutylate, p-menthanehydroperoxide, 2,5-dimethyl-2,5-di(t-butylperoxy)hexane-3, t-butylperoxy benzoate, dicumylperoxide or 2,5-dimethyl-2,5-di(t-butylperoxyhexane), molecular oxygen, or an azo compound such as azobisisobutyronitrile or azoisobutylvaleronitrile.

As the chain transfer agent in the above description, for example, the following can be used: a paraffin hydrocarbon such as methane, ethane, propane, butane or pentane, an α-olefin such as propylene, butene-1, or hexene-1, an aldehyde such as formaldehyde, acetaldehyde, or n-butyraldehyde, a ketone such as acetone, methyl ethyl ketone, or cyclohexanone, an aromatic hydrocarbon, a chlorinated hydrocarbon, or the like.

The method for modifying or condensing the moieties of the silane compound(s) constituting the random copolymer or for modifying or condensing the moieties of the silane compound(s) constituting the graft copolymer in the above description is, for example, a method of using a silanol condensing catalyst, such as a carboxylate of a metal such as tin, zinc, iron, lead or cobalt, an organic metal compound such as an ester or chelate compound of titanic acid, an organic base, an inorganic acid, or an organic acid to cause dehydrating condensation reaction between silanols in the silane compound moieties constituting the random copolymer or graft copolymer of the α-olefin(s) and the ethylenic unsaturated silane compound(s), thereby producing the modified or condensed body of the α-olefin(s) and the ethylenic unsaturated silane compound(s).

In the present invention, it is desired that the content of the ethylenic unsaturated silane compound(s) constituting the copolymer of the α-olefin(s) and ethylenic unsaturated silane compound(s) therein is, for example, from 0.001 to 30% by weight, preferably from 0.01 to 10% by weight, more preferably from 0.01 to 5% by weight.

If the content of the ethylenic unsaturated silane compound(s) constituting the copolymer of the α-olefin(s) and ethylenic unsaturated silane compound(s) in the present invention is large, the mechanical strength, the heat resistance and others are excellent. However, if the content is excessive, the tensile elongation may deteriorate and the ethylenic unsaturated silane compound(s) which is/are in a free state become(s) one or more adhesion inhibitors to result in a tendency that the thermal melting/bonding property is poor. If the content is small, the adhesiveness to the other members may be poor.

In the present invention, the content of the ethylenic unsaturated silane compound(s) is most preferably a content as described above in the material constituting the filler sheet (A) laminated on the front face side and the rear face side of the solar cell element in order to cause the material to exhibit strength, heat resistance, thermal melting/bonding property and other effects.

### (2) Light Resisting Agent, Ultraviolet Absorbent and Thermal Stabilizer

The following will describe a light resisting agent, an ultraviolet absorbent or a thermal stabilizer which constitutes the filler sheet (A) laminated on the front face side and the rear face side of a solar cell element in the present invention. The addition of one or more out of the light resisting agent, the ultraviolet absorbent or the thermal stabilizer in the present invention makes it possible to produce a filler sheet having such as mechanical strength, adhesion strength, anti-yellowing, anti-cracking, excellent work suitability and other properties that are stable over a long term.

### (Light Resistance Agent)

Firstly, as the light resistance agent, there can be used an agent which does not hinder performances of the filler sheet, such as sealing property and transmittance to all rays, and further prevents performances of the filler sheet from being deteriorated by light. For example, a hindered amine type light stabilizer can be used.

Specifically, for example, the following may be used: N,N′, N′″-tetrakis(4,6-bis-(butyl-(N-methyl-2,2,6,6-tetramethylppiperidine-4-yl)amino)-triazine-2-yl)-4,7-diazadecane-1,10-diamine, (a condensate of) dibutylamine-(1,3,5-triazine)-N,N′-bis(2,2,6,6-tetramethyl)-4-piperidyl-1,6-hexamethylenediamine)-N-(2,2,6,6-tetramethyl-4-piperidyl)butylamine, poly[{6-(1,1,3,3-tetramethylbutyl)amino-1,3,5-triazine-2,4-diyl}{(2,2,6,6-tetramethyl-4-piperidyl)imino}hexamethylene{(2,2,6,6-tetramethyl-4-pyperidyl)imino}], a polymer of dimethyl succinate and 4-hydroxy-2,2,6,6-tetramethyl-1-piperidineethanol, a bis(2,2,6,6-tetramethyl-1(octyloxy)-4-piperidinyl) ester of decanedioic acid, a reaction product of 1,1-dimethylethylhydroperoxide and octane, bis(1,2,2,6,6-pentamethyl-4-piperidyl)[[3,5-bis(1,1-dimethylethyl)-4-hydroxyphenyl]methyl]butyl malonate, a mixture of bis(1,2,2,6,6-pentamethyl-4-piperidyl) sebacate and methyl 1,2,2,6,6-pentamethyl-4-piperidyl sebacate, or bis(2,2,6,6-tetramethyl-4-piperidyl) sebacate.

If necessary, these may be used in combination.

It is desired that the added amount thereof, which may be varied in accordance with the kind of the light resisting agent, is from 0.01 to 5% by weight, preferably from 0.01 to 3% by weight, more preferably from 0.01 to 1% by weight of the copolymer of the α-olefin and the ethylenic unsaturated silane compound, or the modified or condensed body thereof.

If the amount is less than the above-mentioned range, the effect of the light resisting agent is insufficient. If the amount is more than the range, the agent may bleed out on the sheet surface to hinder the adhesiveness. Moreover, costs increase. Thus, the case is not preferred.

### (Ultraviolet Absorbent)

Secondly, as the ultraviolet absorbent, for example, the following can be used: an organic compound such as a benzophenone type, benzoate type, triazole type, triazine type, salicylic acid derivative type, or acrylonitrile derivative type compound, or inorganic fine particles made of titanium oxide, zinc oxide or the like.

Specifically, for example, the following can be used: octabenzone, 2-hydroxy-4-n-octoxy-benzophenone, or the like as the benzophenone type, 2,4-di-tert-butylphenyl-3,5-di-tert-butyl-4-hydroxybenzoate, or the like as the benzoate type, 2-[5-chloro(2H)-benzotriazole-2-yl]-4-methyl-6-(tert-butyl) phenol, 2,4-di-tert-butyl-6-(5-chlorobenzotriazole-2-yl)phenol, or the like as the triazole type, or 2-(4,6-diphenyl-1,3,5-triazine-2-yl)-5-[(hexyl)oxy]-phenol, or the like as the triazine type.

If necessary, these may be used in combination.

It is desired that the added amount thereof, which may be varied in accordance with the kind of the ultraviolet absorbent, is from 0.01 to 5% by weight, preferably from 0.01 to 3% by weight, more preferably from 0.01 to 1% by weight of the copolymer of the α-olefin and the ethylenic unsaturated silane compound, or the modified or condensed body thereof.

If the amount is less than the above-mentioned range, the effect of the ultraviolet absorbent is insufficient. If the amount is more than the range, the agent may bleed out on the sheet surface to hinder the adhesiveness. Moreover, costs increase. Thus, the case is not preferred.

### (Thermal Stabilizer)

The thermal stabilizer is used for heat resistance when the resin composition is worked. There can be used, for example, a phosphorus type thermal stabilizer, a phenol type thermal stabilizer, or a lactone type thermal stabilizer.

Specifically, for example, the following can be used: tris(2,4-di-tert-butylphenyl)phosphite, bis[2,4-bis(1,1-dimethylethyl)-6-methylphenyl]ethyl ester phosphorous acid, tetrakis(2,4-di-tert-butylphenyl)[1,1-biphenyl]-4,4′-diyl bisphosphonite, bis(2,4-di-tert-butylphenyl)pentaerythritol diphosphite, or the like as the phosphorus type thermal stabilizer, or a reaction product of 3-hydroxy-5,7-di-tert-butyl-furan-2-one and o-xylene, or the like as the lactone type thermal stabilizer.

If necessary, these may be used in combination.

It is desired that the added amount thereof, which may be varied in accordance with the kind of the thermal stabilizer, is from 0.01 to 5% by weight, preferably from 0.01 to 3% by weight, more preferably from 0.01 to 1% by weight of the copolymer of the α-olefin and the ethylenic unsaturated silane compound, or the modified or condensed body thereof.

If the amount is less than the above-mentioned range, the effect of the thermal stabilizer is insufficient. If the amount is more than the range, the agent may bleed out on the sheet surface to hinder the adhesiveness. Moreover, costs increase. Thus, the case is not preferred.

### (3) Process for Producing a Resin Composition

The following will describe a process for producing a resin composition comprising a copolymer of an α-olefin and an ethylenic unsaturated silane compound, or a modified or condensed body thereof, and one or more of a light resisting agent, an ultraviolet absorbent or a thermal stabilizer in the present invention. Such a resin composition of the invention can be prepared in the form of pellets, powder or the like by adding one or more light resistance agents, ultraviolet absorbents or thermal stabilizers as described above to one or more copolymers of an α-olefin and an ethylenic unsaturated silane compound, or modified or condensed bodies thereof, as described above; optionally adding thereto one or more components other than the above-mentioned components at will as long as the advantageous effects of the present invention are not damaged, specifically adding thereto, for example, various additives that are usually used, such as an antioxidant, a nucleating agent, a neutralizing agent, a lubricant, a blocking preventive, an antistatic agent, a dispersing agent, a fluidity improver, a releasing agent, a flame retardant, a colorant and a filler, at will; optionally adding thereto a solvent, a diluting agent or the like; mixing the components homogeneously by means of a Henschel mixer, a ribbon blender, a V-shaped blender or the like; and melting and kneading the mixture with a uniaxial or multi axial extruder, a roll, a Banbury mixer, a kneader, a Brabender, or the like. The content of the copolymer of the α-olefin and the ethylenic unsaturated silane compound, or the modified or condensed body thereof in the resin composition is preferably 0.01% or more by weight, more preferably 1% or more by weight, even more preferably 3% or more by weight.

In the present invention, a different resin may be added to the above-mentioned resin composition as long as the invention is not damaged, thereby preparing a resin composition.

As the above-mentioned resin, for example, an ethylene-α-olefin copolymer polymerized by use of a metallocene catalyst can be used. However, a substance in which the molecular weight distribution of the polymer as a main polymer is narrow in this manner is somewhat poor in moldability. It is therefore possible to use low density polyethylene, polypropylene or the like which has a different density and add this so as to improve the moldability.

### 2. Filler Sheet (B)

Next, the filler sheet (B) will be described.

The filler sheet (B) is made of a resin film produced by a resin composition comprising a maleic anhydride modified polyolefin, and one or more of a light resisting agent, an ultraviolet absorbent or a thermal stabilizer. The following will describe each component of this resin composition and a process for producing the resin composition.

### (1) Maleic Anhydride Modified Polyolefin

The maleic anhydride modified polyolefin which is used in the present invention and constitutes the filler sheet (B) laminated on both of the front side face and the rear side face of a solar cell element is a substance obtained by polymerizing an α-olefin and an optional different unsaturated monomer to yield a polyolefin polymer, graft-copolymerizing this polymer with maleic anhydride, and then modifying the resultant copolymer. The filler sheet (B) is useful since the use of such a maleic anhydride modified polyolefin therein makes the filler sheet (B) rich in reactivity with polar groups present on the surface of a front face protecting sheet or a rear face protecting sheet, the surface being subjected to surface treatment, so that the sheet (B) can surely keep stable adhesiveness to the protecting sheet. The maleic anhydride modified polyolefin is profitable from the viewpoint of costs also since the polyolefin does not generate any byproducts of low molecular weight compound in the process of adhesion formation so as not to deteriorate working environment.

In the filler sheet (B) of the present invention, only one kind of the maleic anhydride modified polyolefin may be used, or two or more kinds of maleic anhydride modified polyolefins may be used together.

Such a maleic anhydride modified polyolefin can be produced by using a desired reactor to polymerize one or more α-olefins and optional one or more different unsaturated monomers simultaneously or step by step, for example, at a pressure of usually 500 to 4000 kg/cm², preferably 1000 to 4000 kg/cm² and a temperature of usually 100 to 400° C., preferably 150 to 350° C. in the presence of a radical polymerization initiator and an optional chain transfer agent; and next graft-copolymerizing the polyolefin polymer produced by the polymerization with maleic anhydride.

Examples of the α-olefin (s) used in the present invention include ethylene, propylene, 1-butene, isobutylene, 1-pentene, 2-methyl-1-butene, 3-methyl-1-butene, 1-hexene, 1-heptene, 4-methylpentene-1,1-octene, 1-nonene, 1-decene and the like.

Preferred examples of polymer moieties made of the one or more α-olefins include low density polyethylene, middle density polyethylene, high density polyethylene, super low density polyethylene, linear low density polyethylene, polypropylene, and a copolymer made of ethylene and an α-olefin and polymerized by use of a single site catalyst from the viewpoint of transparency, working suitability, adhesiveness, costs, and others.

Of these, linear low density polyethylene is particularly preferred since it has a narrow molecular weight distribution so as not to produce, as a byproduct, a low molecular weight compound originating from a low molecular weight polymer in the process of adhesion formation.

As the different unsaturated monomer(s) optionally used in the above-mentioned polyolefin polymer, the radical polymerization initiator and the chain transfer agent, the same as described about the filler sheet (A) can be used.

The maleic anhydride modified polyolefin used in the present invention is a substance obtained by graft-copolymerizing a polyolefin polymer as described above with maleic anhydride and then modifying the resultant. In the invention, the content ratio of maleic anhydride in this maleic anhydride modified polyolefin is preferably from 0.001 to 30% by weight, more preferably from 0.01 to 10% by weight, even more preferably from 0.01 to 5% by weight.

A case in which the content ratio of maleic anhydride is large is preferred for the following reason: even in the case of using, as a front face protecting sheet, a material poor in adhesiveness such as a fluorine-contained resin sheet subjected to atmospheric pressure plasma treatment or using, as a rear face protecting sheet, a material poor in adhesiveness such as a color steel plate painted with polyester paint, the filler sheet can be bonded strongly to functional groups on the surface thereof to keep adhesive stability surely. However, if the content ratio of maleic anhydride is too large, the production of an unreacted product or a byproduct cannot be controlled to give a low adhesive performance.

In the present invention, the weight-average molecular weight of such a maleic anhydride modified polyolefin is preferably from 1,000 to 1300,000, more preferably from 10,000 to 500,000, even more preferably from 50,000 to 100,000 as obtained by gel permeation chromatography. If the molecular weight is lower than this range, the production of an unreacted product or a byproduct cannot be controlled to give a low adhesive performance. Conversely, if the molecular weight is higher than this range, the transparency deteriorates.

The ratio of the weight-average molecular weight (Mw) to the number-average molecular weight (Mn), (Mw/Mn), is preferably 6 or less, more preferably 5 or less, even more preferably 4 or less. When the ratio is within this range, the generation of a byproduct, resulting from a low molecular weight polymer, is restrained since the dispersion of the molecular weight distribution is narrow.

In the present invention, the number-average molecular weight (Mn) can be obtained from a molecular weight distribution chart obtained by separating molecules of the polymer based on a difference in molecule size by gel permeation chromatography.

### (2) Light Resisting Agent, Ultraviolet Absorbent and Thermal Stabilizer

The resin film constituting the filler sheet (B) of the invention is preferably a resin film obtained by use of a resin composition comprising the above-mentioned maleic anhydride modified polyolefin and additionally one or more of a light resistance agent, an ultraviolet absorbent or a thermal stabilizer. As such a light resistance agent, ultraviolet absorbent or thermal stabilizer which is used in the filler sheet (B), the same as described about the filler sheet (A) can be used. The used amount thereof is preferably within a similar range.

### (3) Process for Producing a Resin Composition

The following will describe a process for producing a resin composition comprising a maleic anhydride modified polyolefin and one or more of a light resisting agent, an ultraviolet absorbent or a thermal stabilizer. Such a resin composition of the invention can be prepared in the form of pellets, powder or the like by adding one or more light resistance agents, ultraviolet absorbents or thermal stabilizers as described above to one or more maleic anhydride modified polyolefins as described above; optionally adding thereto one or more components other than the above-mentioned components at will as long as the advantageous effects of the present invention are not damaged, specifically adding thereto, for example, various additives that are usually used, such as an antioxidant, a nucleating agent, a neutralizing agent, a lubricant, a blocking preventive, an antistatic agent, a dispersing agent, a fluidity improver, a releasing agent, a flame retardant, a colorant and a filler, at will; optionally adding thereto a solvent, a diluting agent or the like; mixing the components homogeneously by means of a Henschel mixer, a ribbon blender, a V-shaped blender or the like; melting and kneading the mixture with a uniaxial or multi axial extruder, a roll, a Banbury mixer, a kneader, a Brabender, or the like. The content of the maleic anhydride modified polyolefin in the resin composition is preferably 0.01% or more by weight, more preferably 1% or more by weight, even more preferably 3% or more by weight.

In the present invention, a different resin may be added to the above-mentioned resin composition as long as the invention is not damaged, thereby preparing a resin composition. It is preferred to use, as the different resin, low-density polyethylene, polypropylene or the like which has a different density for improving the moldability for the same reason as described about filler sheet (A).

### 3. Process for Producing a Filler Sheet

The following will describe a process of using a resin composition comprising a copolymer of an α-olefin and an ethylenic unsaturated silane compound, or a modified or condensed body thereof, and one or more of a light resisting agent, an ultraviolet absorbent or a thermal stabilizer, or a resin composition comprising a maleic anhydride modified polyolefin and one or more of a light resisting agent, an ultraviolet absorbent or a thermal stabilizer in the present invention to form a filler sheet made of a resin film produced by this composition. Examples of such a process include a process of using the resin composition, prepared as described above, according to the invention and molding the resin composition according to the invention into a film or sheet by a molding method that is ordinarily used for ordinary thermoplastic resin, that is, anyone of various molding methods such as injection molding, extrusion molding, hollow molding, compression molding and rotational molding, and then producing a filler sheet using the film or sheet as a resin film.

The case that the resin composition is used in the form of a master batch in the invention and then this is incorporated/molded is preferred since the composition is excellent in dispersibility, moldability and others.

In the present invention, a solar cell module can be produced by using a film or sheet made of the resin composition according to the present invention; and using an ordinary molding process “such as a lamination process of laminating a front face protecting sheet, the film or sheet as a filler layer, a solar cell element as a photoelectromotive force element, the film or sheet as a filler layer, and a rear face protecting sheet in sequence, and next integrating these layers by vacuum suction or the like to heat and compress the layers” to heat, compress and mold the respective layers into an integrated molded body.

Alternatively, in the present invention, the resin composition according to the invention is used, and the resin composition according to the invention is melted, extruded and laminated onto the front face of a solar cell element and the rear face thereof by a molding process ordinarily used for ordinary thermoplastic resin, that is, by any one of various processes such as a T-die extrusion molding, so as to form extruded resin layers made of the resin composition according to the invention on the front face and the rear face of the solar cell element, thereby making it possible to make a filler sheet in which the extruded resin layers are resin films.

In other words, in the present invention, a solar cell module can be produced by using the resin composition according to the invention; melting, extruding and laminating this onto the front face and the rear face of a solar cell element to form extruded resin layers; and next using an ordinary molding process “such as a lamination process of laminating a front protecting sheet, the solar cell element having, on its front face and its rear face, the extruded resin layers as filler layers, and a rear face protecting sheet in sequence, and next integrating these layers by vacuum suction or the like to heat and compress the layers” to heat, compress and mold the respective layers into an integrated molded body.

Furthermore, in the present invention, the resin composition of the invention is used, and the resin composition according to the invention is melted, extruded and laminated onto the front faces of a front face protecting sheet and a rear face protecting sheet by a molding process ordinarily used for ordinary thermoplastic resin, that is, by any one of various processes such as a T-die extrusion molding, so as to form extruded resin layers made of the resin composition according to the invention on the surface of each of the front face protecting sheet and the rear face protecting sheet, thereby making it possible to make a filler sheet in which the extruded resin layers are resin films.

In other words, in the present invention, a solar cell module can be produced by using the resin composition according to the invention; melting, extruding and laminating this on the surface of each of a front face protecting sheet and a rear face protecting sheet to form extruded resin layers; and next using an ordinary molding process “such as a lamination process of laminating the front face protecting sheet, the extruded resin layer as a filler sheet laminated on the surface of the protecting sheet, a solar cell element, the extruded resin layer as a filler sheet laminated on the surface of the rear face protecting sheet, and the rear face protecting sheet in sequence and next integrating these layers by vacuum suction or the like to heat and compress the layers” to heat, compress and mold the above-mentioned respective layers into an integrated molded body.

Moreover, in the present invention, a solar cell module can be produced by forming a p layer, an i layer, an n layer and so on, which constitute an amorphous silicon solar cell element, on the surface of a glass substrate as a front face protecting sheet; next melting, extruding and laminating the resin composition according to the present invention onto the surface of the amorphous silicon solar cell element formed as described above to form an extruded resin layer as a filler sheet; and using an ordinary molding process “such as a lamination process of laminating a rear face protecting sheet on the face of the extruded resin layer, and next integrating these layers by vacuum suction or the like to heat and compress the layers” to heat, compress and mold the above-mentioned respective layers into an integrated molded body.

In the present invention, it is preferred that the film thickness of the filler sheet made of the resin film produced by the resin composition according to the present invention is from 100 μm to 1 mm, preferably from 300 μm to 600 μm.

The filler sheet made of the resin film produced by the resin composition according to the present invention exhibits thermal melting/bonding property and so on by heating and compression performed when a solar cell module is molded, and makes it possible to produce a solar cell module very good in endurance by laminating a front face protecting sheet, the above-mentioned film or sheet as a filler sheet, a solar cell element as a photoelectromotive force element, the above-mentioned film or sheet as a filler sheet, and a rear face protecting sheet in sequence and further thermally melting/bonding these members.

The filler sheet made of the resin film produced by the resin composition according to the present invention does not undergo phenomena that the sheet itself receives effect by action of heat and so on so that the structure and the like thereof breaks or decomposes. Accordingly, the generation of decomposition gas, impurities and so on, which follows the breakdown, decomposition or the like, is not recognized, and this does not produce a bad effect onto a solar cell element and so on. Thus, a solar cell modulus very good in endurance can be produced.

Furthermore, the filler sheet made of the resin film produced by the resin composition according to the present invention is excellent in strength and endurance, is also excellent in various properties such as weatherability, heat resistance, light resistance, water resistance, wind pressure resistance and hailstorm resistance, and is further excellent in scratch resistance and impact absorptivity. Accordingly, a solar cell modulus very good in endurance can be produced.

The gel fraction in the filler sheet for a solar cell module of the present invention is preferably 10% or less, in particular preferably 0%. If the gel fraction is over this range, the workability thereof may lower or the adhesion thereof to a front face protecting sheet or rear face protecting sheet may become insufficient when a solar cell module is produced. The gel fraction in the filler sheet is the gel fraction in the exfoliation layer at the time of producing a solar cell module by using an ordinary molding process “such as a lamination process of laminating, for example, a front face protecting sheet, the filler sheet, a solar cell element, the filler sheet and a rear face protecting sheet in this order, and then integrating, heating and compressing these layers while vacuum-sucking the layers” to integrate the respective layers into a molded body.

### [2] Solar Cell Module

The following will describe a solar cell module according to the present invention produced by use of a filler sheet made of a resin film obtained by the resin composition according to the present invention.

First, a drawing and so on are used to illustrate a layer structure of a solar cell module according to the present invention produced by use of a filler sheet made of a resin film obtained by the resin composition according to the present invention.

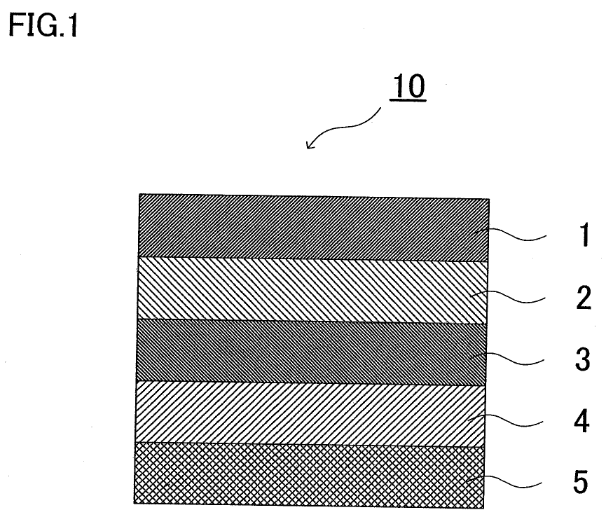

FIG. 1 is a schematic sectional view illustrating an example of the layer structure of the solar cell module according to the invention.

As illustrated in FIG. 1, the solar cell module 10 according to the invention has, as a basic structure, a structure obtained by using an ordinary molding process “such as a lamination process of laminating a front face protecting sheet 1, a filler sheet 2, a solar cell element 3 as a photoelectromotive force element, a filler sheet 4, and a rear face protecting sheet 5 in sequence, and next heating and compressing these layers while vacuum-sucking the layers” to integrate the respective layers into a molded body.

The above-mentioned illustration shows an example of the solar cell module according to the present invention, and the present invention is not limited by this.

For example, a different substrate and the like for the absorption of sunlight, reinforcement and others are arbitrarily added to the above-mentioned solar cell module so as to be laminated and integrated so that a solar cell module can be produced, which is not illustrated. The following will describe the respective layers of the solar cell module according to the present invention in detail.

### 1. Front Face Protecting Sheet

In the above description, the front face protecting sheet which constitutes the solar cell module according to the present invention desirably has various properties such as that the sheet has transmittance of sunlight and electric insulation and is excellent in mechanical, chemical and physical strengths, specifically, the sheet is excellent in various resistance properties such as weatherability, heat resistance, water resistance, light resistance, wind pressure resistance, hailstorm resistance and chemical resistance, in particular light resistance, is excellent in moisture proof property of preventing the invasion of water, oxygen and the like, is high in surface hardness, is excellent in antifouling property of preventing surface contamination and accumulation of dust, is very rich in endurance, and has a high protecting capability.

In the invention, as a front face protecting sheet as described above, specifically, the following can be used: for example, films or sheet made of various resins such as polyethylene resins, polypropylene resins, cyclic polyolefine resins, fluorine-contained resins, polystyrene resins, acrylonitrile-styrene copolymers (AS resins), acrylonitrile-butadiene-styrene copolymers (ABS resins), polyvinyl chloride resins, poly(meth)acrylic resins, polycarbonate resins, polyester resins such as polyethylene terephthalate and polyethylene naphthalate, polyamide resins such as various nylons, polyimide resins, polyamideimide resins, polyaryl phthalate resins, silicone resins, polysulfone resins, polyphenylenesulfide resins, polyethersulfone resins, polyurethane resins, acetal resins, and cellulose resins, as well as a glass plate.

It is particularly preferred to use, out of the above-mentioned resin films or sheets, films or sheets of fluorine-contained resins, cyclic polyolefine resins, polycarbonate resins, poly(meth)acrylic resins, or polyester resins in the invention.

Thus, in the invention, the films or sheets of fluorine-contained resins, cyclic polyolefine resins, polycarbonate resins, poly(meth)acrylic resins, or polyester resins as described above have advantages such that the films or sheets are excellent in mechanical, chemical and physical properties, specifically, excellent in various resistance properties such as weatherability, heat resistance, water resistance, light resistance, moisture proof property, antifouling property and chemical resistance, are light based on the flexibility, mechanical property and chemical property thereof, are excellent in workability, and are easy to handle.

It is particularly preferred in the invention to use, out of various resin films or sheets as described above, fluorine-contained resin sheets made of polyvinyl fluoride resins (PVF) or copolymers of tetrafluoroethylene and ethylene or propylene (ETFE), or cyclic polyolefine resin sheets made of cyclic diene polymers or copolymers such as cyclopentadiene and derivatives thereof, dicyclopentadiene and derivatives thereof, or norbornadiene and derivatives thereof.

Thus, in the invention, the use of fluorine-contained resin sheets or cyclic polyolefine resin sheets as described above is permitted to use excellent properties such as mechanical, chemical and physical properties they have, specifically various properties such as weatherability, heat resistance, water resistance, light resistance, moisture proof property, antifouling property and chemical resistance, thereby preparing the front face protecting sheet constituting a solar cell module. This causes the solar cell module to have advantages such that the module has endurance and a protecting function, is light based on the flexibility, mechanical property and chemical property thereof, is excellent in workability, and is easy to handle.

About the front face protecting sheet used in the invention, it is preferred to dispose a surface-treated layer on the above-mentioned various resin films or sheets in order to improve the adhesion of the front face protecting sheet to the filler sheet.

Such a surface-treated layer can be disposed by conducting a pre-treatment, such as corona discharge treatment, ozone treatment, low-temperature plasma treatment with oxygen gas, nitrogen gas or the like, glow discharge treatment, or oxidation treatment with a chemical or the like, at will so as to form, for example, a corona-treated layer, an ozone-treated layer, a plasma-treated layer, or oxidized layer. Of these, the plasma-treated layer is particularly preferred since gas for the treatment can be selected at will under atmospheric pressure so that a polymer surface can freely be constructed.

It is particularly preferred to use, as the front face protecting sheet of the invention, a front face protecting sheet in which a fluorine-contained resin sheet as described above is used as a substrate and the above-mentioned surface-treated layer, in particular the plasma-treated layer, is disposed thereon. Such a front face protecting sheet has an excellent transparency, a good weatherability, a large mechanical strength, an excellent chemical resistance and stability over a wide temperature range; therefore, excellent in heat resistance and can satisfy required properties such as water resistance, light resistance, moisture proof property and antifouling property.

In the case where the surface-treated layer is disposed on the front face protecting sheet, it is preferred to use, as the filler sheet, the filler sheet (B) of the invention. This is because a maleic anhydride modified polyolefin, which is a constituent material of the filler sheet (B), reacts with polar groups present on the surface-treated layer to keep adhesive stability surely in the interface between the front face protecting sheet and the filler sheet.

In the invention, it is possible to use, as any one of various resin films or sheets, for example, a film or sheet obtained by: using one or more of the above-mentioned various resins and further using a film-forming process, such as an extrusion, cast molding, T-die, cutting or inflation process, to produce the resin film or sheet by a process of forming only one of the various resins into a film, a process of using two or more of the various resins so as to be co-extruded into a multi-layered film, a process of using two or more of the resins, mixing the resins before film-formation, and subsequently forming the mixture into a film, or some other process; and optionally using, for example, a tenter manner or a tubular manner to draw the resultant film or sheet uni-axially or bi-axially.

In the invention, the film thickness of the various resin films or sheets is desirably from 6 to 300 μm, more preferably from 9 to 150 μm.

In the invention, it is desired that the various resin films or sheets have a visible ray transmittance of 90% or more, preferably 95% or more and have a nature that the films or sheets transmit all of incident sunlight rays. In the invention, the visible ray transmittance can be measured with a color computer.

When one or more of the above-mentioned various resins are used to form a film, it is possible to add thereto various plastic compounding agents or additives for improving or modifying the workability, heat resistance, weatherability, mechanical property, dimensional stability, antioxidation, lubricity, releasing property, flame resistance, fungus resistance, electric property, strength and so on of the film. The added amount thereof is any value from an extremely small amount to several tens of percentages dependently on the purpose thereof.

In the above description, ordinary examples of the additives which can be used include a lubricant, a crosslinking agent, an antioxidant, an ultraviolet absorbent, a light stabilizer, a filler, a reinforcing fiber, a reinforcing agent, an antistatic agent, a flame retardant, a flame resisting agent, a foaming agent, an antifungal agent, and a pigment. A reforming resin and the like can also be used.

Thus, in the invention, it is particularly preferred to use the various resin films or sheets into which one or more of the ultraviolet absorbent, antioxidant or reinforcing fiber out of the above-mentioned additives are kneaded in order to improve the weatherability, sticking resistance and others.

The ultraviolet absorbent is an agent for absorbing harmful ultraviolet rays out of sunlight and converting the rays into thermal energy nonpoisonous inside molecules to prevent active species for optical deterioration start in a polymer from being excited. For example, the following can be used: one or more inorganic or organic ultraviolet absorbents such as benzophenone based, benzotriazole based, salicylate based, acrylonitrile based, metallic complex salt based, and hindered amine based compounds, and ultra fine particle titanium oxide (particle size: 0.01 to 0.06 μm) or ultra fine particle zinc oxide (particle size: 0.01 to 0.04 μm).

The antioxidant is an agent for preventing optical deterioration, thermal deterioration or the like of a polymer. For example, a phenol type, an amine type, a sulfur type, or a phosphoric acid type antioxidant can be used.

It is possible to use, as the above-mentioned ultraviolet absorbent or antioxidant, for example, a polymer type ultraviolet absorbent or antioxidant in which the above-mentioned ultraviolet absorbent, such as the benzophenone based absorbent, or the above-mentioned antioxidant, such as the phenol type antioxidant, is chemically bonded to a main chain or side chains which constitute a polymer.

It is possible to use, as the reinforcing fiber, for example, glass fiber, carbon fiber, aramide fiber, polyamide fiber, polyester fiber, polypropylene fiber, polyacrylonitrile fiber or natural fiber. The fiber can be used in a long or short fiber form or in a woven fabric cloth or nonwoven fabric cloth form.

The content of the ultraviolet absorbent, the antioxidant, the reinforcing fiber, or the like is varied by the particle form thereof, the density thereof or the like, and is preferably from 0.1 to 10% by weight.

### 2. Solar Cell Element

The following will describe the solar cell element, as a photoelectromotive force element, which constitutes the solar cell module in the present invention. As such a solar cell element, any one that is ordinarily used can be used, examples of which include crystal silicon solar cell elements such as a monocrystal silicon type solar cell element and a polycrystal silicon type solar cell element; single joint type, tandem structure type, and other type amorphous silicon solar cell elements; gallium arsenide (GaAs), indium phosphorus (InP), and other III-V group compound semiconductor solar cell elements; and cadmium tellurium (CdTe), copper indium selenide (CuInSe₂), and other II-VI group compound semiconductor solar cell elements.

Furthermore, there can be used a thin film polycrystalline silicon solar cell element, a thin film microcrystalline silicon solar cell element, or a hybrid element of a thin film crystal silicon solar cell element and an amorphous silicon solar cell element.

In the invention, the solar cell element is constructed by forming an electromotive force region such as crystal silicon having a pn junction structure or the like, amorphous silicon having a p-i-n junction structure or the like, or a compound semiconductor on a substrate such as a glass substrate, a plastic substrate or a metal substrate.

### 3. Rear Face Protecting Sheet

The following will describe the rear face protecting sheet which constitutes the above-mentioned solar cell module in the invention. Such a rear face protecting sheet needs to have weatherability such as heat resistance, light resistance and water resistance, is excellent in physical or chemical strength and toughness, and is further excellent in scratch resistance, impact absorptivity and so on for protecting the solar cell element as a photoelectromotive force element.

The rear face protecting sheet may not have necessarily such transparency as the above-mentioned front face protecting sheet has, and may or may not have transparency.

Thus, in the invention, as the rear face protecting sheet, for example, an insulating resin film or sheet can be used. Basically, the various resin films or sheets illustrated about the above-mentioned front face protecting sheet can be used in the same manner.

In the invention, as the rear face protecting sheet, specifically, the following can be used: for example, films or sheets made of various resins such as polyethylene resins, polypropylene resins, cyclic polyolefine resins, fluorine-contained resins, polystyrene resins, acrylonitrile-styrene copolymers (AS resins), acrylonitrile-butadiene-styrene copolymers (ABS resins), polyvinyl chloride resins, poly(meth)acrylic resins, polycarbonate resins, polyester resins such as polyethylene terephthalate and polyethylene naphthalate, polyamide resins such as various nylons, polyimide resins, polyamideimide resins, polyaryl phthalate resins, silicone resins, polysulfone resins, polyphenylenesulfide resins, polyethersulfone resins, polyurethane resins, acetal resins, and cellulose resins.

It is particularly preferred to use, out of the above-mentioned resin films or sheets, films or sheets of fluorine-contained resins, cyclic polyolefine resins, polycarbonate resins, poly(meth)acrylic resins, or polyester resins in the invention.

Thus, in the invention, the films or sheets of fluorine-contained resins, cyclic polyolefine resins, polycarbonate resins, poly(meth)acrylic resins, or polyester resins as described above have advantages such that the films or sheets are excellent in mechanical, chemical and physical properties, specifically, excellent in various resistance properties such as weatherability, heat resistance, water resistance, light resistance, moisture proof property, antifouling property and chemical resistance, are useful as protecting sheets constituting solar cells, are excellent in endurance and protecting function property, are light based on the flexibility, mechanical property and chemical property thereof, are excellent in workability, and are easy to handle.

It is particularly preferred in the invention to use, out of various resin films or sheets as described above, for example, the above-mentioned fluorine-contained resin sheets, in particular fluorine-contained resin sheets made of polyvinyl fluoride resins (PVF) or copolymers of tetrafluoroethylene and ethylene or propylene (ETFE), or cyclic polyolefine resin sheets, in particular cyclic polyolefine resin sheets made of cyclopentadiene and derivatives thereof, dicyclopentadiene and derivatives thereof, or norbornadiene and derivatives thereof in the same manner as in the above-mentioned front face protecting sheet.

Thus, in the invention, the use of fluorine-contained resin sheets or cyclic polyolefine resin sheets as described above is permitted to use excellent properties such as mechanical, chemical and physical properties they have, specifically various properties such as weatherability, heat resistance, water resistance, light resistance, moisture proof property, antifouling property and chemical resistance, thereby preparing the rear face protecting sheet constituting a solar cell module. This causes the solar cell module to have advantages such that the module has endurance and a protecting function, is light based on the flexibility, mechanical property and chemical property thereof, is excellent in workability, and is easy to handle.

In the invention, about the above-mentioned various resin films or sheets, it is permissible in the same manner as about the front face protecting sheet that various resin films or sheets are produced and optionally these are further drawn uni-axially or bi-axially.

When one or more of the above-mentioned various resins are used and formed into a film, various plastic compounding agents or additives can be added thereto in the same manner as about the front face protecting sheet.

In the same manner as about the front face protecting sheet, it is preferred to use the various resin films or sheets into which one or more of an ultraviolet absorbent, antioxidant or reinforcing fiber out of the above-mentioned additives are kneaded in order to improve the weatherability, sticking resistance and others.

As the above-mentioned ultraviolet absorbent, one or more inorganic or organic ultraviolet absorbents can be used in the same manner as described above. As the above-mentioned antioxidant, a phenol type, an amine type, a sulfur type, a phosphorus type or some other type antioxidant can be used in the same manner as described above. It is possible to use, as the above-mentioned ultraviolet absorbent or antioxidant, for example, a polymer type ultraviolet absorbent or antioxidant in which the above-mentioned ultraviolet absorbent, such as the benzophenone based absorbent, or the above-mentioned antioxidant, such as the phenol type antioxidant, is chemically bonded to a main chain or side chains which constitute a polymer.

It is possible to use, as the reinforcing fiber, for example, glass fiber, carbon fiber, aramide fiber, polyamide fiber, polyester fiber, polypropylene fiber, polyacrylonitrile fiber or natural fiber in the same manner as described above. The fiber can be used in a long or short fiber form or in a woven fabric cloth or nonwoven fabric cloth form.

The film thickness of the above-mentioned resin films or sheets is desirably from 12 to 200 μm, more preferably from 25 to 150 μm.

In the invention, it is possible to use, as the rear face protecting sheet constituting the solar cell module, a laminate material made by using two or more kinds of resin films or sheets as described above and laminating them through one or more adhesive agent layers or the like, a laminate material made by laminating a metal foil such as aluminum foil on the above-mentioned resin film or sheet, a metal plate, or a resin film or sheet made by coloring or decorating the above-mentioned resin film or sheet with a coloring agent such as dye or pigment, considering the decorative or designable property of the rear face of the solar cell module.

It is preferred in the invention to use, as a member satisfying the required properties of the above-mentioned rear face protecting sheet, the so-called color steel plate, which has a front face on which a painted film is formed.

The steel plate as the original plate of the color steel plate is not particularly limited if the steel plate is ordinarily used in a color steel plate. It is preferred to use a galvanium steel plate, where steel is covered with an alloy of zinc and aluminum, since the plate is excellent in corrosion resistance, workability, heat resistance, heat reflectivity, endurance, and sacrificial rust-proofing effect onto iron.

The painted film is not particularly limited if the painted film can be formed as an insulator film on the steel plate to give corrosion resistance and decorative property thereto. For example, a fluorine-contained resin painted film or a polyester painted film can be preferably used since the fluorine-contained resin painted film is excellent in antifouling property, chemical resistance, corrosion resistance and heat resistance and the polyester painted film is excellent in corrosion resistance and is inexpensive.

When a color steel plate as described above is used as the rear face protecting sheet, it is preferred to use, as the filler sheet, the filler sheet (B) of the invention since the filler sheet (B) can react, because of the use of a maleic anhydride modified polyolefin therein, with polar groups present on the surface of such a painted film, so as to keep surely highly stable adhesiveness to the painted film.

In the invention, the above-mentioned film or sheet can be used in any one of non-drawn form, uni-axially or bi-axially drawn forms, and other forms.

The thickness thereof is selected at will, and can be selected from the range of several micrometers to 3 mm.

In the invention, the film or sheet may be any one of an extruded film, an inflation film, a coating film and other films.

### 4. Other Materials

When the solar cell module according to the invention is produced in the invention, a material selected at will from the following can be used in order to improve the strength thereof and various resistances thereof, such as weatherability and scratch resistance thereof: other materials, for example, films or sheets made of ordinarily used resins, such as low density polyethylene, middle density polyethylene, high density polyethylene, straight chain low density polyethylene, polypropylene, ethylene-propylene copolymers, ethylene-vinyl acetate copolymers, ionomer resins, ethylene-ethyl acrylate copolymers, ethylene-acrylic or methacrylic acid copolymers, methylpentene polymers, polybutene resins, polyvinyl chloride resins, polyvinyl acetate resins, polyvinylidene chloride resins, vinyl chloride-vinylidene chloride copolymers, poly(meth)acrylic resins, polyacrylonitrile resins, polystyrene resins, acrylonitrile-styrene copolymer (AS resins), acrylonitrile-butadiene-styrene copolymers (ABS resins), polyester resins, polyamide resins, polycarbonate resins, polyvinyl alcohol resins, saponified ethylene-vinyl acetate copolymers, fluorine-contained resins, diene resins, polyacetal resins, polyurethane resins, and nitrocellulose.

### 5. Process for Producing the Solar Cell Module

The following will describe a process for producing, in the invention, the solar cell module according to the invention. An example of such a producing process is a process of using an ordinarily used process “such as a lamination process of facing a front face protecting sheet, a filler sheet according to the invention, a solar cell element as a photoelectromotive force element, a filler sheet according to the invention, and a rear face protecting sheet, laminating them in sequence, optionally laminating other materials between the respective layers at will, and next integrating these layers by vacuum-suction or the like to heat and compress the layers” to heat and compress the respective layers into an integrated molded body, thereby producing the solar cell module according to the invention. In this process, it is permissible to use a member in which a front face protecting sheet and a filler sheet are beforehand laminated so as to be integrated, or a member in which a rear face protecting sheet and a filler sheet are beforehand laminated so as to be integrated.

In the above description, in order to make the adhesiveness or the like between the respective layers high, the following can be used if necessary: a hot melt type adhesive agent, a solvent type adhesive agent, a photo curing adhesive agent or the like the vehicle of which is made mainly of a resin such as (meth) acrylic resin, olefin resin, or vinyl resin.

In order to improve the adhesion between laminating and facing faces in the above-mentioned lamination, a pre-treatment can be applied to each of the faces at will if necessary, examples of the treatment including corona discharge treatment, ozone treatment, low-temperature plasma treatment with oxygen gas, nitrogen gas or the like, glow discharge treatment, and oxidation treatment with a chemical or the like.

In the above-mentioned lamination, a surface pre-treatment can be conducted by forming, onto each of the laminating and facing faces, a primer coating agent layer, an undercoating agent layer, an adhesive agent layer, an anchor coating agent layer or the like in advance at will.

As the coating agent layer for the pre-treatment, there can be used, for example, a resin composition the vehicle of which is made mainly of a polyester resin, polyamide resin, polyurethane resin, epoxy resin, phenol resin, (meth)acrylic resin, polyvinyl acetate resin or polyolefin resin such as polyethylene or polypropylene, a copolymer or modified polymer thereof, a cellulose resin, or the like.

In the above description, examples of the method for forming the coating agent layer include roll coating, gravure roll coating, and kiss coating by use of a solvent type, aqueous type or emulsion type coating agent.

In the solar cell module according to the invention, the material constituting its filler sheet can be stably produced at low costs without being affected by such as conditions for producing the solar cell module, thereby making it possible to render this module a solar cell module excellent in strength and various properties such as weatherability, heat resistance, water resistance, light resistance, wind pressure resistance and hailstorm resistance, and very rich in endurance.

Thus, the solar cell according to the invention is suitable for various use purposes, and is used in, for example, a crystal silicon solar cell element, an amorphous solar cell element, a solar cell set on a house roof, which is widely and generally used on the ground, or a solar cell embedded in a house roof, which is of a roof member type.

The amorphous solar cell element can be used in a wristwatch, a calculator or the like for the people's livelihood, and is very useful.

The present invention is not limited to the above-mentioned embodiments. The embodiments are examples, and all products having substantially the same structure as the technical concept described in the claims of the invention and producing the same effect and advantages are included in the invention.

### EXAMPLES

The present invention will be more specifically described by way of examples hereinafter.

### Example 1

### (1) Production of a Filler Sheet (A)

Three parts by weight of vinyltrimethoxysilane and 0.1 part by weight of a free radical generator (t-butyl-peroxyisobutyrate) were mixed with 100 parts by weight of linear low density polyethylene, and the polyethylene was graft-polymerized at an extrusion temperature of 200° C. to prepare a silane-modified linear low density polyethylene having a silane modification ratio of 2%. With 85 parts by weight of the resultant polyethylene were mixed 2.5 parts by weight of a hindered amine type light stabilizer, 7.5 parts by weight of a benzophenone type ultraviolet absorbent and 5 parts by weight of a phosphorus type thermal stabilizer, and then the mixture was melted and worked into a master batch.

To 100 parts by weight of the silane-modified linear low density polyethylene were added 3 parts by weight of the master batch, and then a film-forming machine having an extruder 25 mm in diameter and a T die 300 mm in width was used to form the resin into a film 400 μm in thickness at a resin temperature of 230° C. and a pulling-out rate of 3 m/minute.

The film-formation was carried out without any difficulty.

The above-mentioned resultant film was good in external appearance and transmittance to all rays. About the peel strength thereof to a front face protecting sheet, a rear face protecting sheet and a solar cell element (cell), the film was not easily peeled and was in a good state even after the module was allowed to stand in a state of a high-temperature of 85° C. and a high-humidity of 85% for 1000 hours. Even after the module was subjected to a sunshine weatherometer test (sunshine carbon arc lamp illuminance: 255 W/m², temperature: 60° C., and humidity: 60%) for 500 hours, the film was not easily peeled and was in a good state.

### (2) Production of a Solar Cell Module

The above-mentioned produced film was used as a filler sheet, and the following were laminated through acrylic resin adhesive agent layers: a glass plate 3 mm in thickness, the above-mentioned produced film 400 μm in thickness; a bi-axially drawn polyethylene terephthalate film 38 μm in thickness in which solar cell elements made of amorphous silicon were arranged in parallel; the above-mentioned produced film 400 μm in thickness; and a lamination sheet composed of a polyvinyl fluoride resin sheet (PVF) 38 μm in thickness, an aluminum foil 30 μm in thickness and a polyvinyl fluoride resin sheet (PVF) 38 μm in thickness, as a rear face protecting sheet. A vacuum laminator for solar cell module production was used to press the laminate for pre-bonding at 150° C. for 15 minutes in the state that the solar cell element face thereof was directed upwards, and subsequently the laminate was heated at 150° C. in an oven for 15 minutes, to produce a solar cell module according to the invention.

Even after the solar cell module was allowed to stand in a state of a high-temperature of 85° C. and a high-humidity of 85% for 1000 hours, the external appearance thereof did not change and the lowering of the electromotive force was 5% or less. Even after the module was subjected to a sunshine weatherometer test (sunshine carbon arc lamp illuminance: 255 W/m², temperature: 60° C., and humidity: 60%) for 500 hours, the external appearance thereof did not change and the lowering of the electromotive force was 5% or less.

### Example 2

A filler sheet according to the invention and a solar cell module used were produced in the very same way as in Example 1 except that 0.15 part by weight of vinyltrimethoxysilane was used and the silane modification ratio was set to 0.1%.

The production state of the film, the external appearance, the transmittance to all rays, and the peel strength after the film was allowed to stand in a state of a high-temperature of 85° C. and a high-humidity of 85% for 1000 hours were the same as in Example 1.

The solar cell module produced by use of the film was allowed to stand in a state of a high-temperature of 85° C. and a high-humidity of 85% for 1000 hours, and after this the external appearance and the lowering of the electromotive force were the same as in Example 1. Even after the module was subjected to a sunshine weatherometer test (sunshine carbon arc lamp illuminance: 255 W/m², temperature: 60° C., and humidity: 60%) for 500 hours, the external appearance thereof did not change and the lowering of the electromotive force was 5% or less.

### Example 3

Ten parts by weight of the hindered amine type light stabilizer, 10 parts by weight of the benzophenone type ultraviolet absorbent and 10 parts by weight of the phosphorus type thermal stabilizer were mixed with 70 parts by weight of a silane modified linear low density polyethylene having a silane modification ratio of 4%, produced in the very same way as in Example 1 except that 6 parts by weight of vinyltrimethoxysilane was used, and then the mixture was melted and worked into a master batch.

In the same way as in Example 1 except that to 100 parts by weight of the silane-modified linear low density polyethylene were added 26 parts by weight of the master batch, a film 400 μm in thickness was formed.

The production state of the film, the external appearance, the transmittance to all rays, and the peel strength after the film was allowed to stand in a state of a high-temperature of 85° C. and a high-humidity of 85% for 1000 hours were the same as in Example 1.

The solar cell module produced by use of the film was allowed to stand in a state of a high-temperature of 85° C. and a high-humidity of 85% for 1000 hours, and after this the external appearance and the lowering of the electromotive force were the same as in Example 1. Even after the module was subjected to a sunshine weatherometer test (sunshine carbon arc lamp illuminance: 255 W/m², temperature: 60° C., and humidity: 60%) for 500 hours, the external appearance thereof did not change and the lowering of the electromotive force was 5% or less.

### Example 4

Three parts by weight of the hindered amine type light stabilizer, 6 parts by weight of the benzophenone type ultraviolet absorbent and 6 parts by weight of the phosphorus type thermal stabilizer were mixed with 85 parts by weight of a silane modified linear low density polyethylene having a silane modification ratio of 2%, produced in the same way as in Example 1, and then the mixture was melted and worked into a master batch.

In the same way as in Example 1 except that to 100 parts by weight of the silane-modified linear low density polyethylene was added 1 part by weight of the master batch, a film 400 μm in thickness was formed.

The production state of the film, the external appearance, the transmittance to all rays, and the peel strength after the film was allowed to stand in a state of a high-temperature of 85° C. and a high-humidity of 85% for 1000 hours were the same as in Example 1.

The solar cell module produced by use of the film was allowed to stand in a state of a high-temperature of 85° C. and a high-humidity of 85% for 1000 hours, and after this the external appearance and the lowering of the electromotive force were the same as in Example 1. Even after the module was subjected to a sunshine weatherometer test (sunshine carbon arc lamp illuminance: 255 W/m², temperature: 60° C., and humidity: 60%) for 500 hours, the external appearance thereof did not change and the lowering of the electromotive force was 5% or less.

### Example 5

Three parts by weight of vinylmethoxysilane and 0.1 part by weight of a free radical generator (t-butyl-peroxyisobutyrate) were mixed with 100 parts by weight of linear low density polyethylene, and the polyethylene was graft-polymerized at an extrusion temperature of 200° C. to prepare a silane-modified linear low density polyethylene having a silane modification ratio of 2%.

Next, 2.5 parts by weight of the hindered amine type light stabilizer, 3.5 parts by weight of the benzophenone type ultraviolet absorbent and 5 parts by weight of the phosphorus type thermal stabilizer were mixed with 89 parts by weight of linear low density polyethylene, and then the mixture was melted and worked into a master batch.

To 100 parts by weight of the silane-modified linear low density polyethylene were added 5 parts by weight of the master batch, and the resultant resin was formed into a film 400 μm in thickness by T-die extrusion in the same way as in Example 1.

The film-formation was carried out without any difficulty. The above-mentioned resultant film was good in external appearance and transmittance to all rays. About the peel strength thereof to a front face protecting sheet, a rear face protecting sheet and a cell, the film was not easily peeled and in a good state even after the module was allowed to stand in a state of a high-temperature of 85° C. and a high-humidity of 85% for 1000 hours. After the module was subjected to a sunshine weatherometer test (sunshine carbon arc lamp illuminance: 255 W/m², temperature: 60° C., and humidity: 60%) for 500 hours, the film was not easily peeled and was in a good state.

The above-mentioned produced film was used as a filler sheet to produce a solar cell module according to the invention in the same way as in Example 1. Even after the solar cell module was allowed to stand in a state of a high-temperature of 85° C. and a high-humidity of 85% for 1000 hours, the external appearance thereof did not change and the lowering of the electromotive force was 5% or less. Even after the module was subjected to a sunshine weatherometer test (sunshine carbon arc lamp illuminance: 255 W/m², temperature: 60° C., and humidity: 60%) for 500 hours, the external appearance thereof did not change and the lowering of the electromotive force was 5% or less.

### Example 6

To 20 parts by weight of the silane-modified linear low density polyethylene produced in Example 5 were added 80 parts by weight of linear low density polyethylene and 5 parts by weight of the master batch produced in Example 5. The mixture of the silane-modified linear low density polyethylene, the linear low density polyethylene and the master batch was formed into a film 400 μm in thickness by T-die extrusion in the same way as in Example 1.

The film-formation was carried out without any difficulty. The above-mentioned resultant film was good in external appearance and transmittance to all rays. About the peel strength stability thereof to a front face protecting sheet, a rear face protecting sheet and a cell, the film was not easily peeled and in a good state even after the module was allowed to stand in a state of a high-temperature of 85° C. and a high-humidity of 85% for 1000 hours. After the module was subjected to a sunshine weatherometer test (sunshine carbon arc lamp illuminance: 255 W/m², temperature: 60° C., and humidity: 60%) for 500 hours, the film was not easily peeled and was in a good state.

The above-mentioned produced film was used as a filler sheet to produce a solar cell module according to the invention in the same way as in Example 1. Even after the solar cell module was allowed to stand in a state of a high-temperature of 85° C. and a high-humidity of 85% for 1000 hours, the external appearance thereof did not change and the lowering of the electromotive force was 5% or less. Even after the module was subjected to a sunshine weatherometer test (sunshine carbon arc lamp illuminance: 255 W/m², temperature: 60° C., and humidity: 60%) for 500 hours, the external appearance thereof did not change and the lowering of the electromotive force was 5% or less.

### Example 7

0.0001 part by weight of vinylmethoxysilane and 0.1 part by weight of a free radical generator (t-butyl-peroxyisobutyrate) were mixed with 100 parts by weight of linear low density polyethylene, and the polyethylene was graft-polymerized at an extrusion temperature of 200° C. to prepare a silane-modified linear low density polyethylene having a silane modification ratio of 0.0001%.

Next, 2.5 parts by weight of the hindered amine type light stabilizer, 3.5 parts by weight of the benzophenone type ultraviolet absorbent and 5 parts by weight of the phosphorus type thermal stabilizer were mixed with 89 parts by weight of linear low density polyethylene, and then the mixture was melted and worked into a master batch.

To 100 parts by weight of the silane-modified linear low density polyethylene were added 5 parts by weight of the master batch, and the resin was formed into a film 400 μm in thickness by T-die extrusion in the same way as in Example 1.

The peel strength of the above-mentioned resultant film to a front face protecting sheet, a rear face protecting sheet and a cell was poorer than those of Examples 1 to 6 but was within a practically sufficient range.

The above-mentioned produced film was used as a filler sheet to produce a solar cell module according to the invention in the same way as in Example 1. After the solar cell module was allowed to stand in a state of a high-temperature of 85° C. and a high-humidity of 85% for 1000 hours, interlayer peeling of the film from the front face protecting sheet, the rear face protecting sheet and the cell was partially observed, and the lowering of the electromotive force was over 5% but was within a practically sufficient range.

### Example 8

Forty parts by weight of vinylmethoxysilane and 0.1 part by weight of a free radical generator (t-butyl-peroxyisobutyrate) were mixed with 100 parts by weight of linear low density polyethylene, and the polyethylene was graft-polymerized at an extrusion temperature of 200° C. to prepare a silane-modified linear low density polyethylene having a silane modification ratio of 3%.

Next, 2.5 parts by weight of the hindered amine type light stabilizer, 3.5 parts by weight of the benzophenone type ultraviolet absorbent and 5 parts by weight of the phosphorus type thermal stabilizer were mixed with 89 parts by weight of linear low density polyethylene, and then the mixture was melted and worked into a master batch.

To 100 parts by weight of the silane-modified linear low density polyethylene were added 5 parts by weight of the master batch, and a film 400 μm in thickness was formed by T-die extrusion in the same way as in Example 1.

The peel strength of the above-mentioned resultant film to a front face protecting sheet, a rear face protecting sheet and a cell was poorer than those of Examples 1 to 6 but was within a practically sufficient range.

The above-mentioned produced film was used as a filler sheet to produce a solar cell module according to the invention in the same way as in Example 1. After the solar cell module was allowed to stand in a state of a high-temperature of 85° C. and a high-humidity of 85% for 1000 hours, interlayer peeling of the film from the front face protecting sheet, the rear face protecting sheet and the cell was partially observed, and the lowering of the electromotive force was over 5% but was within a practically sufficient range.

### Example 9

Three parts by weight of vinylmethoxysilane and 0.1 part by weight of a free radical generator (t-butyl-peroxyisobutyrate) were mixed with 100 parts by weight of linear low density polyethylene, and the polyethylene was graft-polymerized at an extrusion temperature of 200° C. to prepare a silane-modified linear low density polyethylene having a silane modification ratio of 2%.

Next, 2.5 parts by weight of the hindered amine type light stabilizer, 0.001 part by weight of the benzophenone type ultraviolet absorbent and 5 parts by weight of the phosphorus type thermal stabilizer were mixed with 92.5 parts by weight of linear low density polyethylene, and then the mixture was melted and worked into a master batch.

To 100 parts by weight of the silane-modified linear low density polyethylene were added 5 parts by weight of the master batch, and the resultant resin was formed into a film 400 μm in thickness by T-die extrusion in the same way as in Example 1.

The film-formation was carried out without any difficulty. The above-mentioned resultant film was good in external appearance and transmittance to all rays. About the peel strength stability thereof to a front face protecting sheet, a rear face protecting sheet and a cell, the stability was unable to be kept and the film was partially peeled after the module was subjected to a sunshine weatherometer test (sunshine carbon arc lamp illuminance: 255 W/m², temperature: 60° C., and humidity: 60%) for 500 hours. Thus, the peel strength stability was poorer than those of Examples 1 to 6 but was within a practically sufficient range.

The above-mentioned produced film was used as a filler sheet to produce a solar cell module according to the invention in the same way as in Example 1. After the solar cell module was subjected to a sunshine weatherometer test (sunshine carbon arc lamp illuminance: 255 W/m², temperature: 60° C., and humidity: 60%) for 500 hours, the lowering of the electromotive force was over 5% but was within a practically sufficient range.

### Example 10

Three parts by weight of vinylmethoxysilane and 0.1 part by weight of a free radical generator (t-butyl-peroxyisobutyrate) were mixed with 100 parts by weight of linear low density polyethylene, and the polyethylene was graft-polymerized at an extrusion temperature of 200° C. to prepare a silane-modified linear low density polyethylene having a silane modification ratio of 2%.

Next, 0.001 part by weight of the hindered amine type light stabilizer, 2.5 parts by weight of the benzophenone type ultraviolet absorbent and 5 parts by weight of the phosphorus type thermal stabilizer were mixed with 91.5 parts by weight of linear low density polyethylene, and then the mixture was melted and worked into a master batch.

To 100 parts by weight of the silane-modified linear low density polyethylene were added 5 parts by weight of the master batch, and the resultant resin was formed into a film 400 μm in thickness by T-die extrusion in the same way as in Example 1.

The film-formation was carried out without any difficulty. The above-mentioned resultant film was good in external appearance and transmittance to all rays. About the peel strength stability thereof to a front face protecting sheet, a rear face protecting sheet and a cell, the stability was unable to be kept and the film was partially peeled after the module was subjected to a sunshine weatherometer test (sunshine carbon arc lamp illuminance: 255 W/m², temperature: 60° C., and humidity: 60%) for 500 hours. Thus, the peel strength stability was poorer than those of Examples 1 to 6 but was within a practically sufficient range.

The above-mentioned produced film was used as a filler sheet to produce a solar cell module according to the invention in the same way as in Example 1. After the solar cell module was subjected to a sunshine weatherometer test (sunshine carbon arc lamp illuminance: 255 W/m², temperature: 60° C., and humidity: 60%) for 500 hours, the lowering of the electromotive force was over 5% but was within a practically sufficient range.

### Example 11

Three parts by weight of vinylmethoxysilane and 0.1 part by weight of a free radical generator (t-butyl-peroxyisobutyrate) were mixed with 100 parts by weight of linear low density polyethylene, and the polyethylene was graft-polymerized at an extrusion temperature of 200° C. to prepare a silane-modified linear low density polyethylene having a silane modification ratio of 2%.

Next, 3.5 parts by weight of the hindered amine type light stabilizer, 2.5 parts by weight of the benzophenone type ultraviolet absorbent and 0.001 part by weight of the phosphorus type thermal stabilizer were mixed with 89 parts by weight of linear low density polyethylene, and then the mixture was melted and worked into a master batch.

To 100 parts by weight of the silane-modified linear low density polyethylene were added 5 parts by weight of the master batch, and the resultant resin was formed into a film 400 μm in thickness by T-die extrusion in the same way as in Example 1. As a result, the resin was oxidized, deteriorated and thermally crosslinked at the time of the extrusion, so that heterogeneous gelation was locally observed in the external appearance of the above-mentioned resultant film. However, the film was practically sufficient.

### Example 12

Three parts by weight of vinylmethoxysilane and 0.1 part by weight of a free radical generator (t-butyl-peroxyisobutyrate) were mixed with 100 parts by weight of linear low density polyethylene, and the polyethylene was graft-polymerized at an extrusion temperature of 200° C. to prepare a silane-modified linear low density polyethylene having a silane modification ratio of 2%.

Next, 2.5 parts by weight of the hindered amine type light stabilizer, 60 parts by weight of the benzophenone type ultraviolet absorbent and 5 parts by weight of the phosphorus type thermal stabilizer were mixed with 32.5 parts by weight of linear low density polyethylene, and then the mixture was melted and worked into a master batch.

To 100 parts by weight of the silane-modified linear low density polyethylene were added 10 parts by weight of the master batch, and the resultant resin was formed into a film 400 μm in thickness by T-die extrusion in the same way as in Example 1.

The film-formation was carried out without any difficulty. The above-mentioned resultant film was good in external appearance and transmittance to all rays. About the peel strength stability thereof to a front face protecting sheet, a rear face protecting sheet and a cell, the stability was unable to be kept and the film was partially peeled after the module was allowed to stand in a state of a high-temperature of 85° C. and a high-humidity of 85% for 1000 hours. Thus, the peel strength stability was poorer than those of Examples 1 to 6 but was within a practically sufficient range.

The above-mentioned produced film was used as a filler sheet to produce a solar cell module according to the invention in the same way as in Example 1. After the solar cell module was allowed to stand in a state of a high-temperature of 85° C. and a high-humidity of 85% for 1000 hours, the lowering of the electromotive force was over 5% but was within a practically sufficient range.

### Example 13

Three parts by weight of vinylmethoxysilane and 0.1 part by weight of a free radical generator (t-butyl-peroxyisobutyrate) were mixed with 100 parts by weight of linear low density polyethylene, and the polyethylene was graft-polymerized at an extrusion temperature of 200° C. to prepare a silane-modified linear low density polyethylene having a silane modification ratio of 2%.

Next, 60 parts by weight of the hindered amine type light stabilizer, 2.5 parts by weight of the benzophenone type ultraviolet absorbent and 5 parts by weight of the phosphorus type thermal stabilizer were mixed with 32.5 parts by weight of linear low density polyethylene, and then the mixture was melted and worked into a master batch.

To 100 parts by weight of the silane-modified linear low density polyethylene were added 10 parts by weight of the master batch, and the resultant resin was formed into a film 400 μm in thickness by T-die extrusion in the same way as in Example 1.

The film-formation was carried out without any difficulty. The above-mentioned resultant film was good in external appearance and transmittance to all rays. About the peel strength stability thereof to a front face protecting sheet, a rear face protecting sheet and a cell, the stability was unable to be kept and the film was partially peeled after the module was allowed to stand in a state of a high-temperature of 85° C. and a high-humidity of 85% for 1000 hours. Thus, the peel strength stability was poorer than those of Examples 1 to 6 but was within a practically sufficient range.

The above-mentioned produced film was used as a filler sheet to produce a solar cell module according to the invention in the same way as in Example 1. After the solar cell module was allowed to stand in a state of a high-temperature of 85° C. and a high-humidity of 85% for 1000 hours, the lowering of the electromotive force was over 5% but was within a practically sufficient range.

### Example 14

Three parts by weight of vinylmethoxysilane and 0.1 part by weight of a free radical generator (t-butyl-peroxyisobutyrate) were mixed with 100 parts by weight of linear low density polyethylene, and the polyethylene was graft-polymerized at an extrusion temperature of 200° C. to prepare a silane-modified linear low density polyethylene having a silane modification ratio of 2%.

Next, 3.5 parts by weight of the hindered amine type light stabilizer, 2.5 parts by weight of the benzophenone type ultraviolet absorbent and 60 parts by weight of the phosphorus type thermal stabilizer were mixed with 32.5 parts by weight of linear low density polyethylene, and then the mixture was melted and worked into a master batch.

To 100 parts by weight of the silane-modified linear low density polyethylene were added 10 parts by weight of the master batch, and the resultant resin was formed into a film 400 μm in thickness by T-die extrusion in the same way as in Example 1.

The film-formation was carried out without any difficulty.

The above-mentioned resultant film was good in external appearance and transmittance to all rays. About the peel strength stability thereof to a front face protecting sheet, a rear face protecting sheet and a cell, the stability was unable to be kept and the film was partially peeled after the module was allowed to stand in a state of a high-temperature of 85° C. and a high-humidity of 85% for 1000 hours. Thus, the peel strength stability was poorer than those of Examples 1 to 6 but was within a practically sufficient range.

The above-mentioned produced film was used as a filler sheet to produce a solar cell module according to the invention in the same way as in Example 1. After the solar cell module was allowed to stand in a state of a high-temperature of 85° C. and a high-humidity of 85% for 1000 hours, the lowering of the electromotive force was over 5% but was within a practically sufficient range.

### Example 15

To 20 parts by weight of the silane-modified linear low density polyethylene produced in Example 5 were added 99.99 parts by weight of linear low density polyethylene and 5 parts by weight of the master batch produced in Example 5. The mixture of the silane modified linear low density polyethylene, the linear low density polyethylene and the master batch was formed into a film 400 μm in thickness by T-die extrusion in the same way as in Example 1.

The film-formation was carried out without any difficulty. The above-mentioned resultant film was good in external appearance and transmittance to all rays. The peel strength of the above-mentioned resultant film to a front face protecting sheet, a rear face protecting sheet and a cell was low, and the film was partially peeled. The peel strength was poorer than those of Examples 1 to 6 but was within a practically sufficient range.

The above-mentioned produced film was used as a filler sheet to produce a solar cell module according to the invention in the same way as in Example 1. After the solar cell module was allowed to stand in a state of a high-temperature of 85° C. and a high-humidity of 85% for 1000 hours, interlayer peeling of the film from the front face protecting sheet, the rear face protecting sheet and the cell was observed, and the lowering of the electromotive force was over 5% but was within a practically sufficient range.

### Example 16

### (1) Production of a Filler Sheet (B)

The following were mixed with each other: 100 parts by weight of a linear low density polyethylene synthesized by copolymerizing ethylene with 1-butene at a ratio of 8% by weight; 2 parts by weight of maleic anhydride; and 3 parts by weight of a free radical generator (t-butyl-peroxybenzoate). The polyethylene was graft-polymerized at an extrusion temperature of 200° C. to prepare a maleic anhydride modified linear low density polyethylene having a maleic anhydride modification ratio of 0.08%. With 85 parts by weight of the resultant polyethylene were mixed 2.5 parts by weight of a hindered amine type light stabilizer, 7.5 parts by weight of a benzophenone type ultraviolet absorbent and 5 parts by weight of a phosphorus type thermal stabilizer, and then the mixture was melted and worked into a master batch.

The weight-average molecular weight of the maleic anhydride modified linear low density polyethylene was 33,700 as measured by a gel permeation chromatography method (GPC method). The ratio of the weight-average molecular weight (Mw) to the number-average molecular weight (Mn), (Mw/Mn), was 1.01.

To 100 parts by weight of the maleic anhydride modified linear low density polyethylene were added 5 parts by weight of the master batch, and then a film-forming machine having an extruder 25 mm in diameter and a T die 300 mm in width was used to form the resin into a film 400 μm in thickness at a resin temperature of 230° C. and a pulling-out rate of 3 m/minute.

The film-formation was carried out without any difficulty. The above-mentioned resultant film was good in external appearance and transmittance to all rays.

About the peel strength thereof, the film was not easily peeled and was in a good state even after the module was allowed to stand in a state of a high-temperature of 85° C. and a high-humidity of 85% for 1000 hours.

### (2) Production of a Solar Cell Module

The above-mentioned produced film was used as a filler sheet, and the following were laminated: an ETFE, 50 μm in thickness, subjected to atmospheric pressure plasma treatment as a front face protecting sheet; the above-mentioned produced film 400 μm in thickness; a polyimide film, 50 μm in thickness, where solar cell elements made of amorphous silicon were arranged in parallel; the above-mentioned produced film 400 μm in thickness; and a color steel plate, 500 μm in thickness, where a polyester coating film was applied onto a galvanium steel plate obtained by covering a steel plate with an alloy of zinc and aluminum, as a rear face protecting sheet. A laminator for solar cell module production was used to press the laminate for pre-bonding at 150° C. for 15 minutes in the state that the solar cell element face thereof was directed upwards, and subsequently the laminate was heated at 150° C. in an oven for 15 minutes, to produce a solar cell module according to the invention.

Even after the solar cell module was allowed to stand in a state of a high-temperature of 85° C. and a high-humidity of 85% for 1000 hours, the external appearance thereof did not change and the lowering of the electromotive force was 5% or less.

### Example 17

The following were mixed with each other: 100 parts by weight of a linear low density polyethylene synthesized by copolymerizing ethylene with 1-butene at a ratio of 8% by weight; 2 parts by weight of maleic anhydride; and 3 parts by weight of a free radical generator (t-butyl-peroxybenzoate). The polyethylene was graft-polymerized at an extrusion temperature of 200° C. to prepare a maleic anhydride modified linear low density polyethylene having a maleic anhydride modification ratio of 0.08%.

Next, 5 parts by weight of the phosphorus type thermal stabilizer were mixed with 95 parts by weight of linear low density polyethylene, and then the mixture was melted and worked into a master batch.

To 100 parts by weight of the maleic anhydride modified linear low density polyethylene were added 5 parts by weight of the master batch, and the resultant resin was formed into a film 400 μm in thickness by T-die extrusion in the same manner as in Example 1.

The film-formation was carried out without any difficulty. The above-mentioned resultant film was good in external appearance and transmittance to all rays. About the peel strength stability thereof to a front face protecting sheet, a rear face protecting sheet and a cell, the film was not easily peeled and was in a good state even after the module was allowed to stand in a state of a high-temperature of 85° C. and a high-humidity of 85% for 1000 hours.

The above-mentioned produced film was used as a filler sheet to produce a solar cell module according to the invention in the same way as in Example 1. Even after the solar cell module was allowed to stand in a state of a high-temperature of 85° C. and a high-humidity of 85% for 1000 hours, the external appearance thereof did not change and the lowering of the electromotive force was 5% or less.

### Example 18

To 20 parts by weight of the maleic anhydride modified linear low density polyethylene produced in Example 17 were added 80 parts by weight of linear low density polyethylene and 5 parts by weight of the master batch produced in Example 17. The mixture of the maleic anhydride modified linear low density polyethylene, the linear low density polyethylene and the master batch was formed into a film 400 μm in thickness by T-die extrusion in the same manner as in Example 1.

The film-formation was carried out without any difficulty. The above-mentioned resultant film was good in external appearance and transmittance to all rays. About the peel strength stability thereof to a front face protecting sheet, a rear face protecting sheet and a cell, the film was not easily peeled and was in a good state even after the module was allowed to stand in a state of a high-temperature of 85° C. and a high-humidity of 85% for 1000 hours.

The above-mentioned produced film was used as a filler sheet to produce a solar cell module according to the invention in the same way as in Example 1. Even after the solar cell module was allowed to stand in a state of a high-temperature of 85° C. and a high-humidity of 85% for 1000 hours, the external appearance thereof did not change and the lowering of the electromotive force was 5% or less.

### Example 19

The following were mixed with each other: 100 parts by weight of a linear low density polyethylene synthesized by copolymerizing ethylene with 1-butene at a ratio of 8% by weight; 0.001 part by weight of maleic anhydride; and 3 parts by weight of a free radical generator (t-butyl-peroxybenzoate). The polyethylene was graft-polymerized at an extrusion temperature of 200° C. to prepare a maleic anhydride modified linear low density polyethylene having a maleic anhydride modification ratio of 0.0001%.

Next, 5 parts by weight of the phosphorus type thermal stabilizer were mixed with 95 parts by weight of linear low density polyethylene, and then the mixture was melted and worked into a master batch.

To 100 parts by weight of the maleic anhydride modified linear low density polyethylene were added 5 parts by weight of the master batch, and then the resultant resin was formed into a film 400 μm in thickness by T-die extrusion in the same manner as in Example 1. The film-formation was carried out without any difficulty.

The peel strength of the above-mentioned resultant film to a front face protecting sheet, a rear face protecting sheet and a cell was low and the film was partially peeled. Thus, the peel strength was poorer than those of Examples 16 to 18 but was within a practically sufficient range.

The above-mentioned produced film was used as a filler sheet to produce a solar cell module according to the invention in the same way as in Example 1. After the solar cell module was allowed to stand in a state of a high-temperature of 85° C. and a high-humidity of 85% for 1000 hours, interlayer peeling of the film from the front face protecting sheet, the rear face protecting sheet and the cell was partially observed, and the lowering of the electromotive force was over 5% but was within a practically sufficient range.

### Example 20

The following were mixed with each other: 100 parts by weight of a linear low density polyethylene synthesized by copolymerizing ethylene with 1-butene at a ratio of 8% by weight; 40 parts by weight of maleic anhydride; and 3 parts by weight of a free radical generator (t-butyl-peroxybenzoate). The polyethylene was graft-polymerized at an extrusion temperature of 200° C. to prepare a maleic anhydride modified linear low density polyethylene having a maleic anhydride modification ratio of 0.1%.

Next, 5 parts by weight of the phosphorus type thermal stabilizer were mixed with 95 parts by weight of linear low density polyethylene, and then the mixture was melted and worked into a master batch.

To 100 parts by weight of the maleic anhydride modified t linear low density polyethylene were added 5 parts by weight of the master batch, and then the resultant resin was formed into a film 400 μm in thickness by T-die extrusion in the same manner as in Example 1.

The peel strength of the above-mentioned resultant film to a front face protecting sheet, a rear face protecting sheet and a cell was low and the film was partially peeled. Thus, the peel strength was poorer than those of Examples 16 to 18 but was within a practically sufficient range.

The above-mentioned produced film was used as a filler sheet to produce a solar cell module according to the invention in the same way as in Example 1. After the solar cell module was allowed to stand in a state of a high-temperature of 85° C. and a high-humidity of 85% for 1000 hours, interlayer peeling of the film from the front face protecting sheet, the rear face protecting sheet and the cell was observed, and the lowering of the electromotive force was over 5% but was within a practically sufficient range.

### Example 21

To 20 parts by weight of the maleic anhydride modified linear low density polyethylene produced in Example 17 were added 99.99 parts by weight of linear low density polyethylene and 5 parts by weight of the master batch produced in Example 17. The mixture of the maleic anhydride modified linear low density polyethylene, the linear low density polyethylene and the master batch was formed into a film 400 μm in thickness by T-die extrusion in the same manner as in Example 1. The film-formation was carried out without any difficulty.

The peel strength of the above-mentioned resultant film to a front face protecting sheet, a rear face protecting sheet and a cell was low and the film was partially peeled. Thus, the peel strength was poorer than those of Examples 16 to 18 but was within a practically sufficient range.

The above-mentioned produced film was used as a filler sheet to produce a solar cell module according to the invention in the same way as in Example 1. After the solar cell module was allowed to stand in a state of a high-temperature of 85° C. and a high-humidity of 85% for 1000 hours, interlayer peeling of the film from the front face protecting sheet, the rear face protecting sheet and the cell was observed, and the lowering of the electromotive force was over 5% but was within a practically sufficient range.

### Comparative Example 1

A glass plate 3 mm in thickness as a substrate was used as a front face protecting sheet for a solar cell module. Onto one face thereof were then laminated an ethylene-vinyl acetate copolymer sheet 400 μm in thickness, a bi-axially drawn polyethylene terephthalate film 38 μm in thickness in which solar cell elements made of amorphous silicon were arranged in parallel, an ethylene-vinyl acetate copolymer sheet 400 μm in thickness, and a bi-axially drawn polyethylene terephthalate film 50 μm in thickness as a rear face protecting sheet through acrylic resin adhesive agent layers in such a manner that the solar cell element face thereof was directed upwards. The same way as in Example 1 was carried out to produce a solar cell module.

### Comparative Example 2

A glass plate 3 mm in thickness as a substrate was used as a front face protecting sheet for a solar cell module Onto one face thereof were then laminated a low density polyethylene sheet 400 μm in thickness, a bi-axially drawn polyethylene terephthalate film 38 μm in thickness in which solar cell elements made of amorphous silicon were arranged in parallel, a low density polyethylene sheet 400 μm in thickness, and a lamination sheet composed of a polyvinyl fluoride resin sheet (PVF) 38 μm in thickness, an aluminum foil 30 μm in thickness, and a polyvinyl fluoride resin sheet (PVF) 38 μm in thickness as a rear face protecting sheet through acrylic resin adhesive agent layers. In the state that the solar cell element face thereof was directed upwards, the same way as in Example 1 was carried out to produce a solar cell module.

### Experiment Example

The solar cell modules produced by use of the filler sheets according to the invention produced in Examples 1 to 21 and the solar cell modules produced by use of the filler layers according to Comparative Examples 1 and 2 were allowed to stand in a state of a high-temperature of 85° C. and a high-humidity of 90% for 1000 hours. Thereafter, the transmittances thereof to all rays were measured, and further a solar cell module evaluating test was made.

### (1) Measurement of Transmittance to All Rays

About the filler sheets used to produce the solar cell modules of the invention in Examples 1 to 21 and the filler layers used to produce the solar cell modules in Comparative Examples 1 and 2, the transmittances (%) thereof to all rays were measured with a color computer.

### (2) Solar Cell Module Evaluating Test

About the solar cell modules produced by use of the filler sheets according to Examples 1 to 21 and the solar cell modules produced by use of the filler layers according to Comparative Examples 1 and 2, a solar cell module environmental test was made based on JIS standard C8917-1989. The photoelectromotive force outputs therefrom before and after the test were measured, and then the results were compared and evaluated.

(3) Measurement of Peel Strength of Filler layer

A cut of 15 mm width was made in the rear face protecting sheet of the rear outermost face and the filler sheet (filler layer) positioned inside it (of each of the modules).

Next, 90-degree peeling was performed at a peel rate of 50 mm/minute at the interface between the polyimide film 38 μm in thickness, where the solar cell elements with the cut of 15 mm width were arranged in parallel, and the filler sheet (filler layer), so as to measure the peel strength.

### (4) Measurement of Peel Strength Stability of Filler Layer to Rear Face Protecting Sheet

The solar cell modules produced by use of the filler sheets (filler layers) according to Examples 1 to 21 and the solar cell modules produced by use of the filler layers according to Comparative Examples 1 and 2 were allowed to stand in a state of a high-temperature of 85° C. and a high-humidity of 90% for 1000 hours, and subsequently a cut of 15 mm width was made in the rear face protecting sheet of the rear outermost face (of each of the modules). At the interface between the rear face protecting sheet and the filler sheet (filler layer), in which the cut of 15 mm width was made, the peel strengths before and after the high-temperature and high-humidity test were measured and compared for evaluation.

### (5) Measurement of Peel Strength Stability of Filler Layer to Front Face Protecting Sheet

The solar cell modules produced by use of the filler sheets (filler layers) according to Examples 1 to 21 and the solar cell modules produced by use of the filler layers according to Comparative Examples 1 and 2 were allowed to stand in a state of a high-temperature of 85° C. and a high-humidity of 90% for 1000 hours. Thereafter, a cut of 15 mm width was made in the front face protecting sheet of the front outermost face (of each of the modules), or the rear face protecting sheet of the rear outermost face, the filler sheet (filler layer) and the film in which the solar cell elements were arranged in parallel, which were positioned inside the rear face protecting sheet, and the filler sheet (filler layer) positioned at the inner side thereof. At the interface between the front face protecting sheet and the filler sheet (filler layer), in which the cut of 15 mm width was made, the peel strengths before and after the high-temperature and high-humidity test were measured and compared for evaluation.

### (6) Measurement of Peel Strength Stability of Filler Layer to Solar Cell Element (Cell)

The solar cell modules produced by use of the filler sheets (filler layers) according to Examples 1 to 21 and the solar cell modules produced by use of the filler layers according to Comparative Examples 1 and 2 were allowed to stand in a state of a high-temperature of 85° C. and a high-humidity of 90% for 1000 hours. Thereafter, a cut of 15 mm width was made in the front face protecting sheet of the front outermost face (of each of the modules), or the rear face protecting sheet of the rear outermost face, the filler sheet (filler layer) and the film in which the solar cell elements were arranged in parallel, which were positioned inside the rear face protecting sheet, and the filler sheet (filler layer) positioned at the inner side thereof. At the interface between the solar cell element and the filler sheet (filler layer), in which the cut of 15 mm width was made, the peel strengths before and after the high-temperature and high-humidity test were measured and compared for evaluation.

Results of the above-mentioned measurement are shown in Table 1.

TABLE 1

| | | | | High temperature and high humidity | | | | | |
|---|---|---|---|---|---|---|---|---|---|
| | | | | for 1000 hours | | | Sunshine weatherometer test for 500 hours | | |
| | Trans- | Lowering | Peel strength | Adhesive | Adhesive | | Adhesive | Adhesive | |
| | mittance | ratio | of filler sheet | stability to rear | stability to front | Adhesive | stability to rear | stability to front | Adhesive |
| | to all | of output | (N/15 mm | face protecting | face protecting | stability to | face protecting | face protecting | stability to |
| | rays (%) | (%) | width) | sheet (%) | sheet (%) | cell (%) | sheet (%) | sheet (%) | cell (%) |
| Example 1 | 91 | −3 | 23 | 96 | 96 | 96 | 96 | 96 | 96 |
| Example 2 | 92 | −2 | 24 | 92 | 94 | — | — | — | — |
| Example 3 | 91 | −3 | 24 | 98 | 97 | — | — | — | — |
| Example 4 | 91 | −2 | 22 | 96 | 97 | — | — | — | — |
| Example 5 | 92 | −2 | 25 | 95 | 95 | 95 | 95 | 95 | 95 |
| Example 6 | 94 | −1 | 27 | 94 | 94 | 94 | 94 | 94 | 94 |
| Example 7 | 93 | −15 | 1 | — | — | — | — | — | |
| Example 8 | 91 | −16 | 5 | — | — | — | — | — | |
| Example 9 | 92 | −20 | 26 | 96 | 96 | 96 | 30 | 30 | 30 |
| Example 10 | 93 | −23 | 23 | 95 | 95 | 95 | 38 | 38 | 38 |
| Example 11 | 82 | −12 | 20 | 90 | 90 | 90 | 90 | 90 | 90 |
| Example 12 | 92 | −25 | 21 | 30 | 30 | 30 | 30 | 30 | 30 |
| Example 13 | 91 | −26 | 22 | 38 | 38 | 38 | 38 | 38 | 38 |
| Example 14 | 93 | −28 | 20 | 38 | 38 | 38 | 38 | 38 | 38 |
| Example 15 | 94 | −18 | 0.5 | — | — | — | — | — | — |
| Example 16 | 92 | −3 | 23 | 85 | 92 | 96 | 85 | 92 | 96 |
| Example 17 | 93 | −2 | 26 | 85 | 92 | 96 | 85 | 92 | 96 |
| Example 18 | 91 | −4 | 23 | 85 | 92 | 96 | 85 | 92 | 96 |
| Example 19 | 94 | −13 | 1 | — | — | — | — | — | — |
| Example 20 | 93 | −15 | 2 | — | — | — | — | — | — |
| Example 21 | 92 | −14 | 1 | — | — | — | — | — | — |
| Comparative | 89 | −50 | 16 | 30 | 86 | 85 | — | — | — |
| Example 1 | | | | | | | | | |
| Comparative | 92 | −43 | 0.2 | 0.2 | 0.1 | 0.1 | — | — | — |
| Example 2 | | | | | | | | | |

As is evident from the measurement results shown in Table 1, the filler sheets according to Examples 1 to 21 had a high transmittance to all rays and a low output lowering ratio, and were practically sufficient. Furthermore, the filler sheet according to Examples 1 to 21 were excellent in peel strength and were also excellent in peel strength stability to the front face protecting sheet and the rear face protecting sheet.

On the other hand, filler layers according to Comparative Examples 1 and 2 had a high transmittance to all rays but the solar cell modules using the layers had problems such as that the output lowering ratio was high. Furthermore, the filler layers according to Comparative Examples 1 and 2 were poor in peel strength and also low in adhesive stability to the respective protecting sheets.

1. A filler sheet for solar cell, which is formed as a filler sheet laminated on front face and rear face sides of a solar cell element, and is made of a resin film produced by a resin composition comprising a maleic anhydride modified polyolefin.

2. The filler sheet for solar cell according to claim 1, wherein the resin composition further comprises one or more selected from a group consisting of a light resisting agent, an ultraviolet absorbent and a thermal stabilizer.

3. The filler sheet for solar cell according to claim 1, wherein the maleic anhydride modified polyolefin is a substance modified by graft-copolymerizing a polyolefin with maleic anhydride, and a content ratio of maleic anhydride in the maleic anhydride modified polyolefin ranges from 0.001 to 30% by weight.

4. The filler sheet for solar cell according to claim 1, wherein the maleic anhydride modified polyolefin has a weight-average molecular weight of 1,000 to 1300,000, the molecular weight being obtained by a gel permeation chromatography, and a ratio of the weight-average molecular weight (Mw) to a number-average molecular weight (Mn), (Mw/Mn), is 6 or less.

5. The filler sheet for a solar cell module according to claim 2, wherein the light resisting agent is made of a hindered amine type light stabilizer.

6. The filler sheet for a solar cell module according to claim 2, wherein the ultraviolet absorber is made of a benzophenone type, triazole type, salicylic acid derivative type, or acrylonitrile derivative type ultraviolet absorbent.

7. The filler sheet for a solar cell module according to claim 2, wherein the thermal stabilizer is made of a phosphorus type thermal stabilizer, a phenol type thermal stabilizer, or a lactone type thermal stabilizer.

8. The filler sheet for a solar cell module according to claim 2, wherein the light resisting agent is contained at a content ratio of 0.01 to 5% by weight of the maleic anhydride modified polyolefin.

9. The filler sheet for a solar cell module according to claim 2, wherein the ultraviolet absorbent is contained at the content ratio of 0.05 to 5% by weight of the maleic anhydride modified polyolefin.

10. The filler sheet for a solar cell module according to claim 2, wherein the thermal stabilizer is contained at the content ratio of 0.05 to 5% by weight of the maleic anhydride modified polyolefin.

11. A solar cell module made by laminating a front face protecting sheet, a filler sheet, a solar cell element, a filler sheet and a rear face protecting sheet in sequence so as to be integrated, wherein the filler sheets are each the filler sheet for a solar cell module according to claim 1.

12. The solar cell module according to claim 11, wherein the front face protecting sheet is made of a glass plate, a fluorine-contained resin sheet, a cyclic polyolefine resin sheet, a polycarbonate resin sheet, a poly(meth) acrylic resin sheet, a polyamide resin sheet, or a polyester resin sheet.

13. The solar cell module according to claim 11, wherein the solar cell element is made of a crystal silicon solar cell element or an amorphous silicon solar cell element.

14. The solar cell module according to claim 11, wherein the rear face protecting sheet is made of a metal plate or metal foil, a fluorine-contained resin sheet, a cyclic polyolefine resin sheet, a polycarbonate resin sheet, a poly(meth)acrylic resin sheet, a polyamide resin sheet, or a polyester resin sheet.

15. The solar cell module according to claim 11, wherein the front face protecting sheet and the filler sheet are beforehand laminated and integrated with each other.

16. The solar cell module according to claim 11, wherein the rear face protecting sheet and the filler sheet are beforehand laminated and integrated with each other.

17. The solar cell module according to claim 11, wherein a gel fraction in each of the filler sheets is 10% or less.
